(19) United States
(12) Patent Application Publication
(10) Pub. No.: US 2025/0120074 A1
(43) Pub. Date: Apr. 10, 2025

(54) DEVICES AND METHODS FOR MANUFACTURING DEVICES

(71) Applicant: Taiwan Semiconductor Manufacturing Company, Ltd., Hsinchu (TW)

(72) Inventors: Meng-Sheng Chang, Hsinchu (TW); Chia-En Huang, Hsinchu (TW); Yih Wang, Hsinchu (TW)

(21) Appl. No.: 18/484,237

(22) Filed: Oct. 10, 2023

(51) Int. Cl. H10B 20/00; G11C 17/18; H10B 20/25

(52) U.S. Cl. CPC H10B 20/60; H10B 20/25; G11C 17/18

(57) ABSTRACT

A memory device including a substrate, a sense amplifier that includes first gate-all-around transistors that have first drain/source regions that extend into the substrate, and bit cells that include fuse memory elements and second gate-all-around transistors. Each of the bit cells includes a fuse memory element having a first terminal connected to an input of the sense amplifier and a second terminal connected to a second gate-all-around transistor that includes second drain/source regions and a bottom dielectric isolation layer under the second drain/source regions.

### BACKGROUND

Semiconductor devices include different types of memory, such as random-access memory (RAM), read-only memory (ROM), and electrical fuse (eFuse) memory. The eFuse memory is a programmable non-volatile memory (NVM) that does not lose data when power is removed from the semiconductor device. Typically, eFuses are integrated into the semiconductor device using narrow strips of conductive material, referred to as fuse links, situated between terminals. To program an eFuse, current is applied to the fuse link to change the resistivity of the fuse link. The state of the eFuse, i.e., whether it has been programmed, is read using a sensing circuit, such as a sense amplifier.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating a semiconductor device that includes a bit cell memory array and a sensing circuit configured to provide an output voltage Vout, in accordance with some embodiments.

FIG. 2 is a diagram schematically illustrating the semiconductor device including the bit cell memory array and peripheral circuitry, in accordance with some embodiments.

FIG. 3 is a diagram schematically illustrating a gate-all-around (GAA) metal-oxide semiconductor field-effect transistor (MOSFET) that includes drain/source regions that extend into a substrate of the semiconductor device, in accordance with some embodiments.

FIG. 4 is a diagram schematically illustrating the GAA MOSFET with drain/source regions that extend to a depth D1 in the substrate, in accordance with some embodiments.

FIG. 5 is a diagram schematically illustrating the GAA MOSFET with drain/source regions that extend to a depth D2 in the substrate, in accordance with some embodiments.

FIG. 6 is a diagram schematically illustrating a bit cell of the bit cell memory array, in accordance with some embodiments.

FIG. 7 is a diagram schematically illustrating a super bottom isolation (SBI) GAA MOSFET, in accordance with some embodiments.

FIG. 8 is a diagram schematically illustrating a flexible bottom isolation (FBI) GAA MOSFET, in accordance with some embodiments.

FIG. 9 is a diagram schematically illustrating a graph of the off current Ioff of different GAA MOSFETs, in accordance with some embodiments.

FIG. 10 is a diagram schematically illustrating the bit cell as a stacked indium gallium zinc oxide (IGZO) device, in accordance with some embodiments.

FIG. 11 is a diagram schematically illustrating bit cells that each include an SBI GAA MOSFET of FIG. 7 coupled to the sense amplifier, in accordance with some embodiments.

FIG. 12 is a diagram schematically illustrating bit cells that each include an FBI GAA MOSFET of FIG. 8 coupled to the sense amplifier, in accordance with some embodiments.

FIG. 13 is a diagram schematically illustrating a bit cell memory array that includes bit cells electrically connected to the sense amplifier, in accordance with some embodiments.

FIG. 14 is a diagram schematically illustrating a bit cell memory array that includes bit cells electrically connected to a sense amplifier that includes n-channel GAA MOSFETs that are each either an SBI GAA MOSFET or an FBI GAA MOSFET, in accordance with some embodiments.

FIG. 15 is a diagram schematically illustrating stacked IGZO device bit cells coupled to the sense amplifier, in accordance with some embodiments.

FIG. 16 is a diagram schematically illustrating a high-density memory device, in accordance with some embodiments.

FIG. 17 is a diagram schematically illustrating a layout of the high-density memory device, in accordance with some embodiments.

FIG. 18 is a diagram schematically illustrating a two transistor anti-fuse bit cell, in accordance with some embodiments.

FIG. 19 is a diagram schematically illustrating another high-density memory device, in accordance with some embodiments.

FIG. 20 is a diagram schematically illustrating a layout of the high-density memory device of FIG. 20, in accordance with some embodiments.

FIG. 21 is a diagram schematically illustrating the deposition of an oxide layer in a semiconductor device, such as the semiconductor device of FIG. 1 and/or of FIG. 2, in accordance with some embodiments.

FIG. 22 is a diagram schematically illustrating a TiN deposition and photo patterning of the TiN deposition to form two TiN gates on the oxide layer, in accordance with some embodiments.

FIG. 23 is a diagram schematically illustrating a high-k dielectric deposition and photo patterning of the high-k dielectric on the TiN gates, in accordance with some embodiments.

FIG. 24 is a diagram schematically illustrating an IGZO active region deposition and photo patterning to provide the IGZO active region deposited on the high-k dielectric, in accordance with some embodiments.

FIG. 25 is a diagram schematically illustrating a TiN layer deposition and photo patterning to form drain/source regions in the Tin layer, in accordance with some embodiments.

FIG. 26 is a diagram schematically illustrating an oxide layer deposition, in accordance with some embodiments.

FIG. 27 is a diagram schematically illustrating contact etching through the oxide layer to provide via holes to the drain/source regions, in accordance with some embodiments.

FIG. 28 is a diagram schematically illustrating conductive routing, such as via and metal layer routing, to contact the drain/source regions of the IGZO transistors, in accordance with some embodiments.

FIG. 29 is a diagram schematically illustrating a method of manufacturing a semiconductor device, in accordance with some embodiments.

FIG. 30 is a diagram schematically illustrating another method of manufacturing a semiconductor device, in accordance with some embodiments.

FIG. 31 is a diagram schematically illustrating an alternative method of manufacturing a semiconductor device, in accordance with some embodiments.

FIG. 32 is a block diagram schematically illustrating an example of a computer system configured to provide the semiconductor devices and methods of the current disclosure, in accordance with some embodiments.

FIG. 33 is a block diagram of a semiconductor device manufacturing system and a semiconductor device manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Often, an eFuse bit cell includes a fuse link and a circuit for programming and reading the eFuse. Historically, the fuse link takes up a large area in the semiconductor device. In some embodiments, the fuse links are manufactured in a metal layer, such as a metal 2 layer. However, utilizing the metal 2 layer to manufacture the fuse links includes drawbacks, such as being unable to use the metal 2 layer for other routing considerations, and being unable to reduce the bit cell memory area due to design rule requirements between fuse links on the same metal layer.

In some embodiments, a bit cell includes one transistor and one resistive fuse link (1T1R). Each of the fuse links is electrically connected to a transistor for programming and reading the eFuse. In some embodiments, the transistor in the 1T1R bit cell is a gate-all-around (GAA) metal-oxide semiconductor field-effect transistor (MOSFET) manufactured in a nanosheet process. In some embodiments, these GAA transistors have drain/source regions that extend into a substrate, such that the GAA transistors have large off currents Ioff. As a result, unselected bits have large leakage currents, which may result in high resistance, read 1 errors. For example, if a high resistance value is being read from a selected bit and large leakage currents from unselected bits are included in the sensed current, the total current may surpass a read 1 margin of the sense amplifier resulting in a read 1 error. This is especially a problem at higher temperatures where the leakage currents, i.e., the off currents, of the unselected bits are larger.

Disclosed embodiments provide a semiconductor device that has an improved read 1 margin, where the off current Ioff of unselected bits is reduced and the read 1 margin is increased. In some embodiments, the semiconductor device includes bit cells that each have a GAA MOSFET that has a bottom dielectric layer situated under the drain/source regions of the MOSFET, which reduces the off current Ioff of the GAA MOSFET. In some embodiments, the semiconductor device includes bit cells that each include an indium gallium zinc oxide (IGZO) device that includes an IGZO transistor, with a reduced off current Ioff, connected to a fuse memory element, such as a metal fuse.

In some embodiments, the semiconductor device includes a substrate, a sense amplifier that includes first GAA transistors that have first drain/source regions that extend into the substrate, and bit cells that include second GAA transistors that each include second drain/source regions and a bottom dielectric isolation layer situated under the second drain/source regions, where each of the second GAA transistors is connected to a fuse memory element. In some embodiments, each of the second GAA transistors includes the bottom dielectric isolation layer in contact with the second drain/source regions.

Further disclosed embodiments provide a semiconductor device that includes stacked IGZO devices situated above sense amplifiers in a high-density memory. In some embodiments, the semiconductor device includes a substrate, at least one sense amplifier that includes GAA transistors that have first drain/source regions that extend into the substrate, and bit cells that include IGZO transistors, where each of the bit cells is connected to the at least one sense amplifier and configured to store at least one bit of data in a fuse memory element or in an anti-fuse memory element. In some embodiments, each of the IGZO transistors is connected to a fuse memory element. In some embodiments, each of the bit cells includes at least two IGZO transistors connected in series to provide an anti-fuse bit cell. In some embodiments, each of the bit cells includes more than two IGZO transistors connected to provide a memory element, such as an anti-fuse memory element.

Further disclosed embodiments include semiconductor devices with different layouts or designs and methods of forming the semiconductor devices described herein.

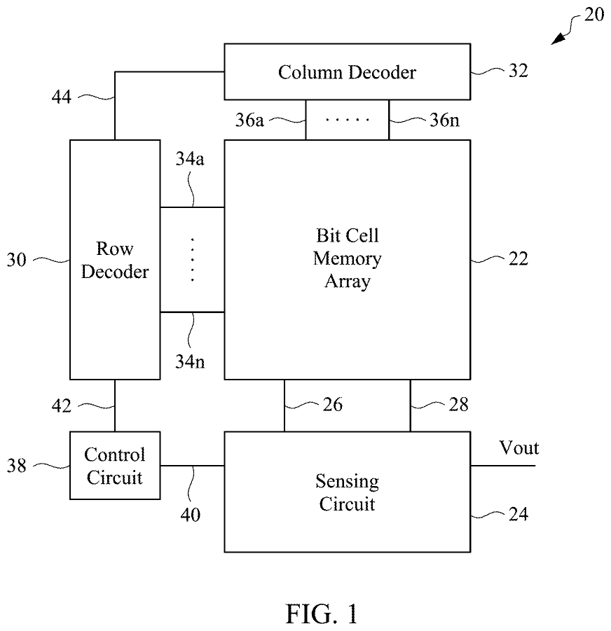

FIG. 1 is a diagram schematically illustrating a semiconductor device 20 that includes a bit cell memory array 22 and a sensing circuit 24 configured to provide an output voltage Vout, in accordance with some embodiments. The bit cell memory array 22 is electrically connected to the sensing circuit 24 by memory array conductive paths 26 and 28. In some embodiments, the semiconductor device 20 is an integrated circuit.

The semiconductor device 20 includes the bit cell memory array 22, a row decoder circuit 30, and a column decoder circuit 32. The bit cell memory array 22 includes bit cells arranged in an x-y grid. The row decoder circuit 30 is electrically connected to the bit cell memory array 22 by row lines 34a-34n that extend in the x-direction. The column decoder circuit 32 is electrically connected to the bit cell memory array 22 by column lines 36a-36n that extend in the y-direction. The rows extend along the x-axis and the columns extend along the y-axis of the x-y grid of the bit cell memory array 22.

In some embodiments, the bit cell memory array 22 includes eFuse memory elements. In some embodiments, the bit cell memory array 22 includes anti-fuse memory elements. In some embodiments, the bit cell memory array 22 includes 1T1R memory elements. In some embodiments, the bit cell memory array 22 includes 1T1C memory elements. In some embodiments, the bit cell memory array 22 includes NTMR memory elements, where N>0 and M>0. In some embodiments, the bit cell memory array 22 includes NTMC memory elements, where N>0 and M>0. In some embodiments, the bit cell memory array 22 includes multiple transistor, such as two transistor, anti-fuse memory elements. In some embodiments, the bit cell memory array 22 is one of a static random-access memory (SRAM), a resistive random-access memory (RRAM), a phase-change random-access memory (PCRAM), and a magneto-resistive random-access memory (MRAM).

The semiconductor device 20 includes a control circuit 38 that is electrically connected to the sensing circuit 24 by conductive path 40 and to the row decoder circuit 30 and the column decoder circuit 32 by conductive paths 42 and 44. The row decoder circuit 30 receives and decodes row addresses and the column decoder circuit 32 receives and decodes column addresses. Also, the sensing circuit 24, the row decoder circuit 30, and the column decoder circuit 32 receive instructions from the control circuit 38 to control operation of the semiconductor device 20.

The sensing circuit 24 includes a sense amplifier configured to read selected bit cells of the bit cell memory array 22. The bit cell memory array 22 and the sensing circuit 24 provide improved read 1 margins, where the off current Ioff of unselected bits is reduced and the read 1 margin is increased. Also, the semiconductor device 20 includes circuits for programming the bit cells. In some embodiments, the programming circuits for programming the bit cells are in the sensing circuit 24.

In some embodiments, the semiconductor device 20 includes bit cells that each have a GAA MOSFET that has a bottom dielectric layer situated under the drain/source regions of the MOSFET, which reduces the off current Ioff of the GAA MOSFET. In some embodiments, the semiconductor device 20 includes bit cells that each have at least one IGZO transistor, which reduces the off current Ioff of the unselected bit cells and improves the read 1 margin of the sensing circuit 24.

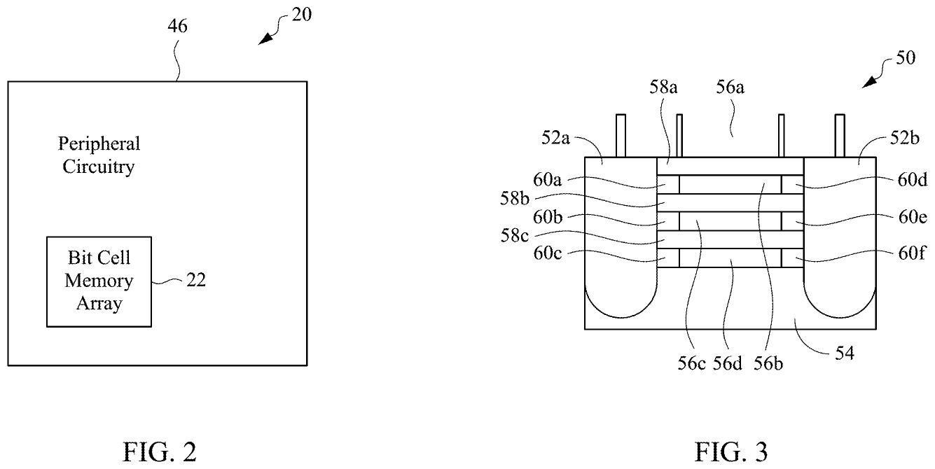

FIG. 2 is a diagram schematically illustrating the semiconductor device 20 including the bit cell memory array 22 and peripheral circuitry 46, in accordance with some embodiments. The peripheral circuitry 46 includes one or more sense amplifiers. In some embodiments, the peripheral circuitry 46 includes the sensing circuit 24, the row decoder 30, the column decoder 32, and the control circuit 38.

The bit cell memory array 22 includes bit cells that each include an eFuse memory element and a circuit for programming and reading the eFuse memory element. In some embodiments, the circuit for programming and reading the eFuse is formed in one plane of the semiconductor device 20 and the eFuse is formed in a different plane of the semiconductor device 20. In some embodiments, the circuit for programming and reading the eFuse is formed in a plane of the semiconductor device 20 that is below a plane of the semiconductor device 20 that includes the eFuse. In some embodiments, the eFuse is formed in a metal layer that is in a plane of the semiconductor device 20 above the plane that includes the circuit for programming and reading the eFuse. In some embodiments, the eFuse is formed in a metal layer, such as a metal 2 layer.

The semiconductor device 20, including the bit cell memory array 22 and the sensing circuit 24, provides an improved read 1 margin, where the off current Ioff of unselected bits is reduced and the read 1 margin is increased. Each of the bit cells in the bit cell memory array 22 includes an eFuse and a circuit for programming and reading an eFuse. In some embodiments, each circuit for programming and reading an eFuse includes a transistor that has a lower off current Ioff, such that leakage currents are reduced and the read 1 margin is increased. In some embodiments, each circuit for programming and reading an eFuse includes a GAA MOSFET that has a bottom dielectric layer situated under the drain/source regions of the MOSFET, which reduces the off current Ioff of the GAA MOSFET and increases the read 1 margin. In some embodiments, each circuit for programming and reading an eFuse includes an IGZO transistor that has a lower off current Ioff, which increases the read 1 margin.

The peripheral circuitry 46, including the sensing circuit 24 that includes one or more sense amplifiers, includes GAA MOSFETs that have drain/source regions that extend into a substrate of the semiconductor device 20. Each of these GAA MOSFETs has a higher off current Ioff than a GAA MOSFET with a bottom dielectric layer situated under the drain/source regions of the MOSFET, and a higher off current Ioff than an IGZO transistor. In some embodiments, the GAA MOSFETs that have drain/source regions that extend into the substrate are formed in a plane of the semiconductor circuit 20 that is the same plane that includes the circuits for programming and reading the eFuses, such as the GAA MOSFETs with a bottom dielectric layer. In some embodiments, the GAA MOSFETs that have drain/source regions that extend into the substrate are formed in a plane of the semiconductor circuit 20 that is the same plane that includes the circuits for programming and reading the eFuses, such as the IGZO transistors. In some embodiments, the peripheral circuitry 46 including the GAA MOSFETs that have drain/source regions that extend into the substrate is formed in a plane of the semiconductor circuit 20 that is a different plane than, such as a plane below, the plane that includes the IGZO transistors, such that the semiconductor device 20 can have a higher density memory. In some embodiments, the GAA MOSFETs are manufactured in a nanosheet process. In other embodiments, the GAA MOSFETs are other transistors, such as planar transistors, fin field-effect-transistors (finFETs), CFETs, and fork-nanosheet transistors.

FIG. 3 is a diagram schematically illustrating a GAA MOSFET 50 that includes drain/source regions 52a and 52b that extend into a substrate 54 of the semiconductor device 20, in accordance with some embodiments. The peripheral circuitry 46, including the one or more sense amplifiers, is manufactured using the GAA MOSFET 50.

The GAA MOSFET 50 includes metal-over-gate (MG) contacts 56a-56d on each side of silicon channels 58a-58c. Inner spacers 60a-60f separate the MG contacts 56b-56d from the drain/source regions 52a and 52b.

In operation, the GAA MOSFET 50 has a higher off current Ioff than a GAA MOSFET that has a bottom dielectric layer situated under the drain/source regions of the MOSFET, and a higher off current Ioff than an IGZO transistor.

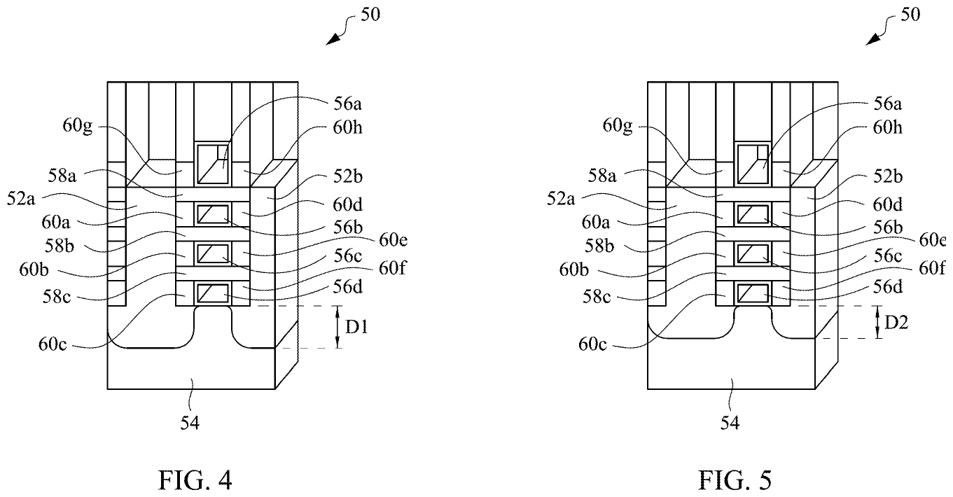

FIGS. 4 and 5 are diagrams schematically illustrating the GAA MOSFET 50 with drain/source regions 52a and 52b that extend to different depths D1 and D2 in the substrate 54, in accordance with some embodiments.

FIG. 4 is a diagram schematically illustrating the GAA MOSFET 50 with drain/source regions 52a and 52b that extend to a depth D1 in the substrate 54, in accordance with some embodiments, and FIG. 5 is a diagram schematically illustrating the GAA MOSFET 50 with drain/source regions 52a and 52b that extend to a depth D2 in the substrate 54, in accordance with some embodiments. The depth D1 is greater than the depth D2.

In each of the FIGS. 4 and 5, the GAA MOSFET 50 includes MG contacts 56a-56d on each side of silicon channels 58a-58c, and inner spacers 60a-60h that separate the MG contacts 56a-56d from the drain/source regions 52a and 52b.

In operation, the GAA MOSFET 50 with drain/source regions 52a and 52b that extend to a depth D1 in the substrate 54 has a higher off current Ioff (leakage current) than the GAA MOSFET 50 with drain/source regions 52a and 52b that extend to a depth D2 in the substrate 54. Also, each of the GAA MOSFETs 50 of FIGS. 4 and 5 has a higher off current Ioff than the GAA MOSFET that has a bottom dielectric layer situated under the drain/source regions of the MOSFET, and a higher off current Ioff than an IGZO transistor.

In some embodiments, the peripheral circuitry 46, including the one or more sense amplifiers, uses the GAA MOSFET 50 of FIG. 4. In some embodiments, the peripheral circuitry 46, including the one or more sense amplifiers, uses the GAA MOSFET 50 of FIG. 5.

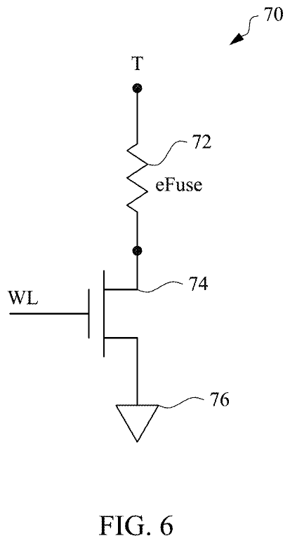

FIG. 6 is a diagram schematically illustrating a bit cell 70 of the bit cell memory array 22, in accordance with some embodiments. The bit cell 70 includes an eFuse 72 and an n-channel MOSFET 74 that is the circuit for programming and reading the eFuse 72. In some embodiments, each of the other bit cells in the bit cell memory array 22 is like the bit cell 70. In some embodiments, the bit cell 70 is an IGZO device. In some embodiments, the n-channel MOSFET 74 is a GAA MOSFET that includes a bottom dielectric layer. In some embodiments, the eFuse 72 is formed in a metal layer, such as a metal 2 layer.

One terminal T of the eFuse 72 is configured to be electrically connected to a programming circuit and/or to one of the sense amplifiers, such as in the sensing circuit 24. The other terminal of the eFuse 72 is electrically connected to one drain/source region of the MOSFET 74. Another drain/source region of the MOSFET 74 is electrically connected to a reference 76, such as ground. The gate of the MOSFET 74 is electrically connected to receive a select signal, such as a word line signal WL.

In operation, to program the bit cell 70, the word line signal WL is set to a high voltage to bias on the MOSFET 74, and current is passed through the eFuse 72 to change the resistance of the eFuse 72 to a high resistance value.

To read the state of the bit cell 70, i.e., to read whether the bit cell 70 has been programmed, the eFuse 72 is connected to a sense amplifier in the sensing circuit 24 and the word line signal WL is set to a high voltage to select the bit cell 70 and bias on the MOSFET 74. At least some of the other bit cells in the bit cell memory array 22 are connected to the sense amplifier in the sensing circuit 24, however, the other bit cells 70 are unselected, such as by receiving a low voltage in the word line signals. This biases off the MOSFETs in the unselected bit cells. The state of the selected bit cell 70 is determined from the amount of current that flows through the eFuse 72.

Each of the unselected bit cells that are connected to the sense amplifier provide an off current Ioff, i.e., a leakage current, that is received by the sense amplifier in the sensing circuit 24. If the selected bit 70 is programmed to a high resistance, i.e., a read 1 resistance, and the current received by the sense amplifier from the selected bit cell 70 summed with the leakage currents from the other bit cells exceeds a read 1 margin, the sense amplifier provides a read 1 error. Reducing the off currents avoids providing a read 1 error.

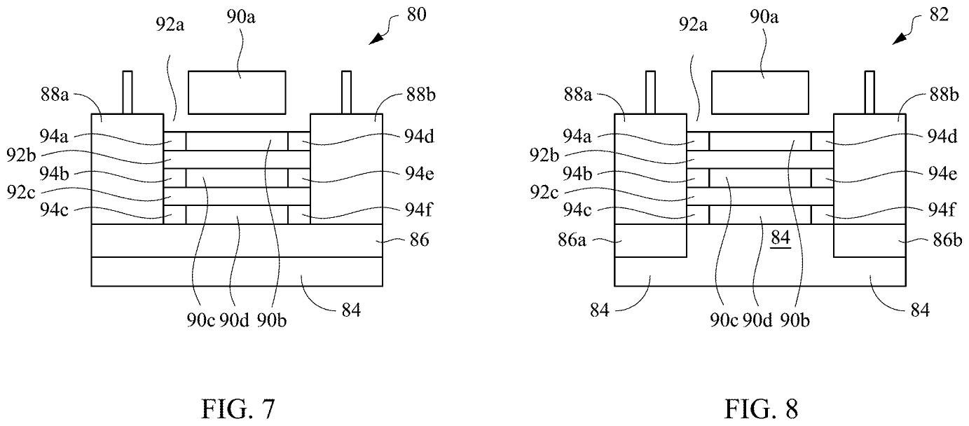

FIGS. 7 and 8 are diagrams schematically illustrating the MOSFET 74 as a super bottom isolation (SBI) GAA MOSFET 80 and as a flexible bottom isolation (FBI) GAA MOSFET 82, in accordance with some embodiments. Each of the GAA MOSFETs 80 and 82 can be used in the bit cell 70 of the bit cell memory array 22. Also, each of the GAA MOSFETs 80 and 82 includes a substrate 84 and a bottom dielectric layer 86, including the bottom dielectric layer 86 in the SBI GAA MOSFET 80 and the bottom dielectric layer segments 86a and 86b in the FBI GAA MOSFET 82, situated under the drain/source regions 88a and 88b of the MOSFET, where the bottom dielectric layer 86 and the bottom dielectric layer segments 86a and 86b situated under the drain/source regions 88a and 88b of the MOSFET reduce the off current Ioff, i.e., the leakage current, of the MOSFET.

Advantages of each of the SBI GAA MOSFET 80 and the FBI GAA MOSFET 82 includes a reduction in the off current Ioff, i.e., a reduction in the leakage current, of a bit cell 70, an increased read 1 margin, and improved operations at minimum power voltages, such as VDDmin.

FIG. 7 is a diagram schematically illustrating an SBI GAA MOSFET 80, in accordance with some embodiments. The SBI GAA MOSFET 80 includes the substrate 84 and the bottom dielectric layer 86 that is formed on the substrate 84. A first drain/source region 88a is formed on one side of the bottom dielectric layer 86 and a second drain/source region 88b is formed on another side of the bottom dielectric layer 86. The bottom dielectric layer 86 is in contact with each of the first and second drain/source regions 88a and 88b and extends across the gate region of the SBI GAA MOSFET 80, from the first drain/source region 88a to the second drain/source region 88b.

The SBI GAA MOSFET 80 includes MG contacts 90a-90d on each side of silicon channels 92a-92c. Inner spacers 94a-94f separate the MG contacts 90b-90d from the drain/source regions 88a and 88b.

In operation, the SBI GAA MOSFET 80 has a lower off current Ioff than the GAA MOSFET 50 of FIGS. 3, 4, and 5, which has the drain/source regions 52a and 52b that extend into the substrate 54.

FIG. 8 is a diagram schematically illustrating an FBI GAA MOSFET 82, in accordance with some embodiments. The FBI GAA MOSFET 82 includes the substrate 84 and the bottom dielectric layer segments 86a and 86b that are formed on the substrate 84. A first drain/source region 88a is formed on a first bottom dielectric layer segment 86a and a second drain/source region 88b is formed on a second bottom dielectric layer segment 86b. The first bottom dielectric layer segment 86a is in contact with the first drain/source region 88a and the second bottom dielectric layer segment 86b is in contact with the second drain/source region 88b. The first and second dielectric layer segments 86a and 86b do not extend across the gate region of the FBI GAA MOSFET 82.

The FBI GAA MOSFET 82 includes MG contacts 90a-90d on each side of silicon channels 92a-92c. Inner spacers 94a-94f separate the MG contacts 90b-90d from the drain/source regions 88a and 88b.

In operation, the FBI GAA MOSFET 82 has a lower off current Ioff than the GAA MOSFET 50 of FIGS. 3, 4, and 5, which has the drain/source regions 52a and 52b that extend into the substrate 54.

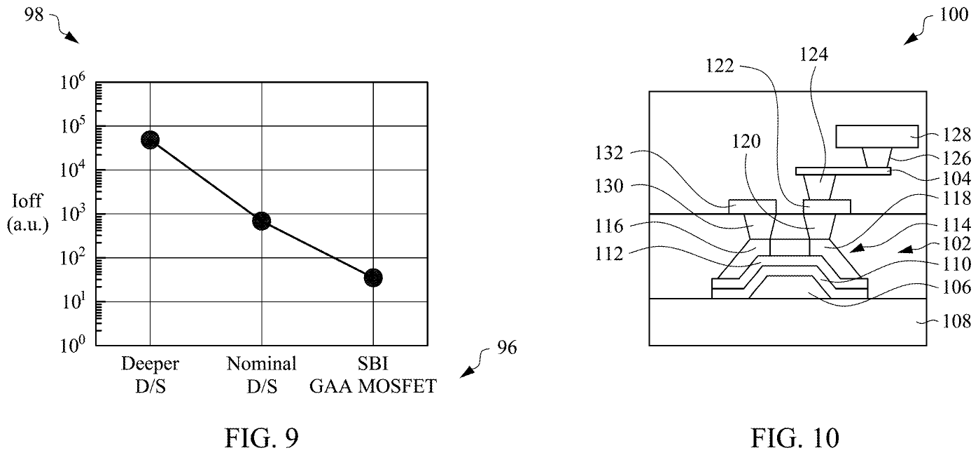

FIG. 9 is a diagram schematically illustrating a graph of the off current Ioff of different GAA MOSFETs, in accordance with some embodiments. The GAA MOSFETs are graphed along the x-axis 96 and the off current Ioff is graphed on a logarithmic scale on the y-axis 98. The different GAA MOSFETs include a GAA MOSFET 50 having drain/source regions 52a and 52b that extend deeper in the substrate 54 to a depth of D1 as in FIG. 4 (Deeper D/S), a GAA MOSFET 50 having drain/source regions 52a and 52b that extend a nominal distance in the substrate 54 to a depth of D2 as in FIG. 5 (Nominal D/S), and an SBI GAA MOSFET 80 that includes a bottom dielectric layer 86 as in FIG. 7.

The GAA MOSFET 50 having drain/source regions 52a and 52b that extend deeper in the substrate 54 to a depth of D1 as in FIG. 4 (Deeper D/S) has an off current Ioff of about 30,000 atomic units (a.u.). The GAA MOSFET 50 having drain/source regions 52a and 52b that extend in the substrate 54 to a depth of D2 as in FIG. 5 (Nominal D/S) has a reduced off current Ioff of about 600 a.u., and the SBI GAA MOSFET 80 that includes a bottom dielectric layer 86 as in FIG. 7 has a further reduced off current Ioff of about 20 a.u. In some embodiments, the FBI GAA MOSFET 82 that includes the bottom dielectric layer segments 86a and 86b provides an off current Ioff that is like the off current Ioff of the SBI GAA MOSFET 80.

FIG. 10 is a diagram schematically illustrating the bit cell 70 as a stacked IGZO device 100, in accordance with some embodiments. The semiconductor device 20 includes the stacked IGZO device 100 in the bit cell memory array 22, and the peripheral circuitry 46 includes transistors like GAA MOSFET 50 of FIGS. 3, 4, and 5, which have the drain/source regions 52a and 52b that extend into the substrate 54. In some embodiments, the semiconductor device 20 includes stacked IGZO devices, such as the stacked IGZO device 100, situated above the sense amplifiers of the peripheral circuitry 46 in a stacked high-density memory.

The stacked IGZO device 100 is a 1T1R bit cell device. The stacked IGZO device 100 includes an IGZO transistor 102 electrically connected to an eFuse memory element 104. The IGZO transistor 102 includes a titanium nitride (TiN) gate 106 deposited on an oxide layer 108. A high-k dielectric 110, such as hafnium dioxide (HfO2), is deposited on the TiN gate 106, and an IGZO active region 112 is deposited on the high-k dielectric 110. A TiN layer 114 is deposited and patterned on the IGZO active region 112 to form the drain/source regions 116 and 118 of the IGZO transistor 102. The drain/source region 118 is electrically connected through via 120, contact layer 122, and via 124 to the eFuse memory element 104, such as a metal fuse. The eFuse memory element 104 is further electrically connected to another via 126 and contact layer 128. The drain/source region 116 is electrically connected to a via 130 and a contact layer 132.

In operation, the stacked IGZO device 100 has a lower off current Ioff than the GAA MOSFET 50 of FIGS. 3, 4, and 5, which has the drain/source regions 52a and 52b that extend into the substrate 54.

Advantages of the stacked IGZO device 100 include a reduction in the off current Ioff, i.e., a reduction in the leakage current, an increased read 1 margin, a smaller area of the bit cell 70, and a higher density memory.

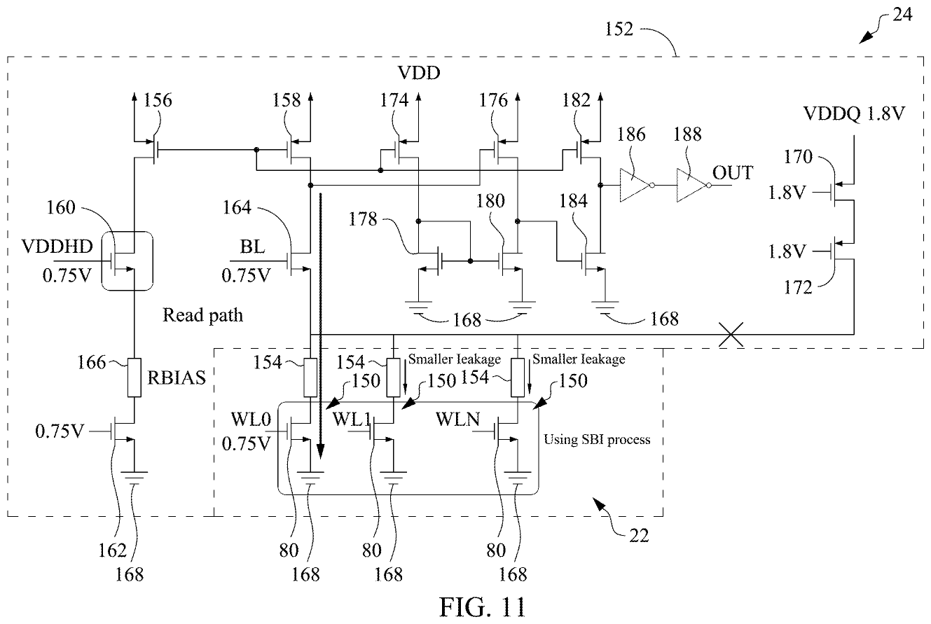

FIGS. 11-15 are diagrams schematically illustrating different embodiments of the bit cell memory array 22 and the sensing circuit 24 in the semiconductor device 20 of FIG. 1, in accordance with some embodiments. The bit cell memory array 22 includes bit cells 150 and the sensing circuit 24 includes a sense amplifier 152. The bit cells 150 and/or the sense amplifier 152 include different transistors in the different embodiments.

FIG. 11 is a diagram schematically illustrating bit cells 150 that each include an SBI GAA MOSFET 80 of FIG. 7 coupled to the sense amplifier 152, in accordance with some embodiments. Each of the bit cells 150 includes an SBI GAA MOSFET 80 electrically connected to an eFuse memory element 154 that is electrically connected to the sense amplifier 152. The sense amplifier 152 includes n-channel and p-channel GAA MOSFETS like GAA MOSFET 50 of FIGS. 3, 4, and 5, which have the drain/source regions 52a and 52b that extend into the substrate 54. The bit cells 150 are part of the bit cell memory array 22 and the sense amplifier 152 is part of the sensing circuit 24 in the semiconductor device 20 of FIG. 1. In some embodiments, the eFuse memory element 154 is a metal fuse link.

The sense amplifier 152 includes a bias circuit that includes a first p-channel MOSFET 156, a second p-channel MOSFET 158, a first n-channel MOSFET 160, a second n-channel MOSFET 162, and a third n-channel MOSFET 164. One drain/source region of the first p-channel MOSFET 156 is electrically connected to VDD and the other drain/source region of the first p-channel MOSFET 156 is electrically connected to one drain/source region of the first n-channel MOSFET 160. The other drain/source region of the first n-channel MOSFET 160 is electrically connected to one end of a bias resistor 166 and the other end of the bias resistor 166 is electrically connected to one drain/source region of the second n-channel MOSFET 162. The other drain/source region of the second n-channel MOSFET 162 is electrically connected to a reference 168, such as ground.

The gate of the first p-channel MOSFET 156 is electrically connected to the gate of the second p-channel MOSFET 158, and one drain/source region of the second p-channel MOSFET 158 is electrically connected to VDD. The other drain/source region of the second p-channel MOSFET 158 is electrically connected to one drain/source region of the third n-channel MOSFET 164. The other drain/source region of the third n-channel MOSFET 164 is electrically connected to the bit cells 150 and to a bit cell circuit that includes a third p-channel MOSFET 170 and a fourth p-channel MOSFET 172. One drain/source region of the third p-channel MOSFET 170 is electrically connected to VDDQ (1.8 volts) and the other drain/source region of the third p-channel MOSFET 170 is electrically connected to one drain/source region of the fourth p-channel MOSFET 172. The other drain/source region of the fourth p-channel MOSFET 172 is electrically connected to the drain/source region of the third n-channel MOSFET 164 and the bit cells 150. The gates of the third p-channel MOSFET 170 and the fourth p-channel MOSFET 172 receive a gate voltage, such as 1.8 volts.

The sense amplifier 152 further includes a current mirror circuit that includes a fifth p-channel MOSFET 174, a sixth p-channel MOSFET 176, a fourth n-channel MOSFET 178, and a fifth n-channel MOSFET 180. One drain/source region of the fifth p-channel MOSFET 174 is electrically connected to VDD and the other drain/source region of the fifth p-channel MOSFET 174 is electrically connected to one drain/source region and the gate of the fourth n-channel MOSFET 178 and to the gate of the fifth n-channel MOSFET 180. The other drain/source region of the fourth n-channel MOSFET 178 is electrically connected to the reference 168. Also, one drain/source region of the sixth p-channel MOSFET 176 is electrically connected to VDD and the other drain/source region of the sixth p-channel MOSFET 176 is electrically connected to one drain/source region of the fifth n-channel MOSFET 180. The other drain/source region of the fifth n-channel MOSFET 180 is electrically connected to the reference 168. The gate of the fifth p-channel MOSFET 174 is electrically connected to the gates of the first and second p-channel MOSFETs 156 and 158, and the gate of the sixth p-channel MOSFET 176 is electrically connected to the drain/source region of the second p-channel MOSFET 158.

The sense amplifier 152 further includes an output circuit that includes a seventh p-channel MOSFET 182, a sixth n-channel MOSFET 184, a first inverter 186, and a second inverter 188. One drain/source region of the seventh p-channel MOSFET 182 is electrically connected to VDD and the other drain/source region of the seventh p-channel MOSFET 182 is electrically connected to one drain/source region of the sixth n-channel MOSFET 184 and to an input of the first inverter 186. The other drain/source region of the sixth n-channel MOSFET 184 is electrically connected to the reference 168. The gate of the seventh p-channel MOSFET 182 is electrically connected to the gates of the first, second, and fifth p-channel MOSFETs 156, 158, and 174 and the gate of the sixth n-channel MOSFET 184 is electrically connected to the drain/source region of the fifth n-channel MOSFET 180.

The bit cell memory array 22 includes the bit cells 150. Each of the bit cells 150 includes an SBI GAA MOSFET 80 electrically connected to an eFuse memory element 154 that is electrically connected to the sense amplifier 152. One end of each eFuse memory element 154 is electrically connected to the drain/source region of the third n-channel MOSFET 164 and the other end of the eFuse memory element 154 is connected to one drain/source region of the SBI GAA MOSFET 80. The other drain/source region of the SBI GAA MOSFET 80 is electrically connected to the reference 168.

In operation, to read the state of one of the bit cells 150, one of the gates of the SBI GAA MOSFETs 80 in the bit cells 150, such as the gate that receives word line WL0, is set to a high voltage, such as 0.75 volts. This biases on the SBI GAA MOSFET 80 in the selected bit cell 150. The other gates of the other SBI GAA MOSFETs 80 in the other bit cells 150 receive a low voltage, such as ground, to bias off the SBI GAA MOSFETs 80.

In sensing the status of the selected bit cell 150, the gate of the first n-channel MOSFET 160, the gate of the second n-channel MOSFET 162, and the gate of the third n-channel MOSFET 164 each receive a high voltage, such as 0.75 volts, to bias on the first, second, and third n-channel MOSFETs 160, 162, and 164. This provides a bias current through the first p-channel MOSFET 156, the first n-channel MOSFET 160, the bias resistor 166, and the second n-channel MOSFET 162. The gate of the second p-channel MOSFET 158 is at the same voltage as the gate of the first p-channel MOSFET 156 and the second p-channel MOSFET 158 is biased to provide current along the read path through the third n-channel MOSFET 164 and the selected bit cell 150. Also, the second p-channel MOSFET 158 provides leakage current for the unselected and biased off other bit cells 150.

The gate of the fifth p-channel MOSFET 174 is biased to the gate voltage of the first and second p-channel MOSFETs 156 and 158 to provide a current in the current mirror circuit and the gate of the sixth p-channel MOSFET 176 is biased to the voltage at the drain/source region of the second p-channel MOSFET 158. In addition, the gate of the seventh p-channel MOSFET 182 is biased to the gate voltage of the first and second p-channel MOSFETs 156 and 158 to provide current in the output circuit.

If the selected bit cell 150 is unprogrammed it provides a low resistance path through the selected bit cell 150 to the reference 168. The current provided by the second p-channel MOSFET 158 to the selected bit cell 150 and to the unselected bit cells 150 (in the form of leakage current) pulls the drain/source region of the second p-channel MOSFET 158 to a low voltage that biases on the sixth p-channel MOSFET 176 to provide a high voltage at the drain/source region of the fifth n-channel MOSFET 180. This biases on the sixth n-channel MOSFET 184, which provides a low voltage at the input of the first inverter 186, a high voltage at the input of the second inverter 188, and a low voltage (read 0) at the output OUT.

If the selected bit cell 150 is programmed, it provides a high resistance path through the selected bit cell 150 to the reference 168. The current provided by the second p-channel MOSFET 158 to the selected bit cell 150 and to the unselected bit cells 150 (in the form of leakage current) is small and pulls the drain/source region of the second p-channel MOSFET 158 to a high voltage that biases off the sixth p-channel MOSFET 176 to provide a low voltage at the drain/source region of the fifth n-channel MOSFET 180. This biases off the sixth n-channel MOSFET 184, which pulls the drain/source region of the seventh p-channel MOSFET 182 to a high voltage at the input of the first inverter 186, a low voltage at the input of the second inverter 188, and a high voltage (read 1) at the output OUT.

If a programmed high resistance is being read from the selected bit cell 150 and leakage currents of the unselected bit cells 150 are large, the total sensed current may surpass a read 1 margin of the sense amplifier 152, resulting in a read 1 error. However, with each of the bit cells 150 including an SBI GAA MOSFET 80, the leakage current of the unselected bit cells 150 is reduced and the sense amplifier 152 does not provide a read 1 error. Advantages of using the SBI GAA MOSFET 80 in the bit cells 150 include a reduction in the off current Ioff, i.e., a reduction in the leakage current, of a bit cell 150, an increased read 1 margin, and improved operations at minimum power voltages, such as VDDmin.

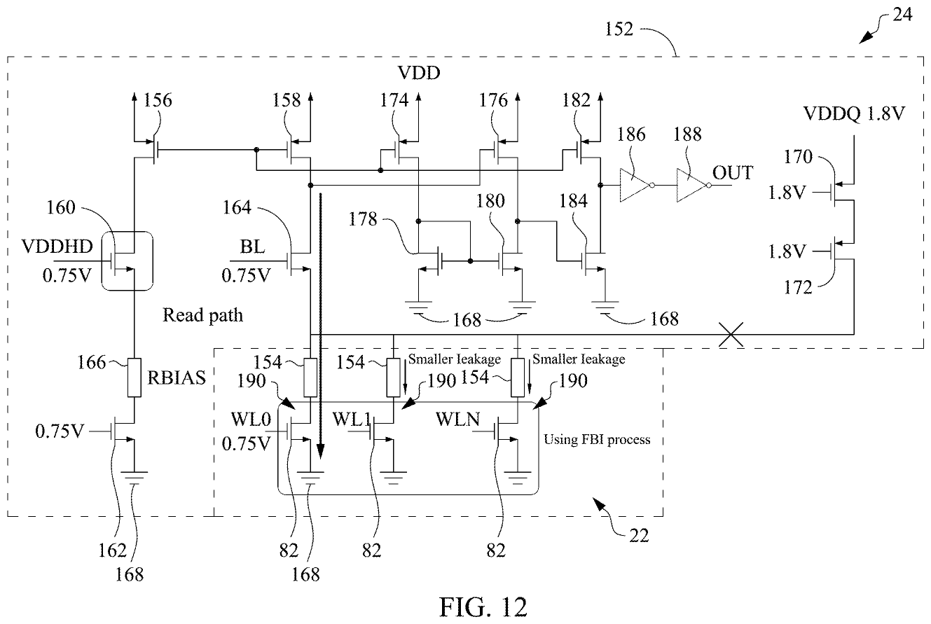

FIG. 12 is a diagram schematically illustrating bit cells 190 that each include an FBI GAA MOSFET 82 of FIG. 8 coupled to the sense amplifier 152, in accordance with some embodiments. Each of the bit cells 190 includes an FBI GAA MOSFET 82 electrically connected to an eFuse memory element 154 that is electrically connected to the sense amplifier 152. The sense amplifier 152 includes n-channel and p-channel GAA MOSFETS like GAA MOSFET 50 of FIGS. 3, 4, and 5, which have the drain/source regions 52a and 52b that extend into the substrate 54. The bit cells 190 are part of the bit cell memory array 22 and the sense amplifier 152 is part of the sensing circuit 24 in the semiconductor device 20 of FIG. 1. In some embodiments, the eFuse memory element 154 is a metal fuse link.

The bit cell memory array 22 includes the bit cells 190. Each of the bit cells 190 includes an FBI GAA MOSFET 82 electrically connected to an eFuse memory element 154 that is electrically connected to the sense amplifier 152. One end of each eFuse memory element 154 is electrically connected to the drain/source region of the third n-channel MOSFET 164 and the other end of the eFuse memory element 154 is connected to one drain/source region of the FBI GAA MOSFET 82. The other drain/source region of the FBI GAA MOSFET 82 is electrically connected to the reference 168.

The sense amplifier 152 is like the sense amplifier 152 shown in FIG. 11, such that the description of the sense amplifier 152 is not repeated here. Also, the sense amplifier 152 operates to read the state of one of the bit cells 190 as described in relation to the sense amplifier 152 and the bit cells 150 shown in FIG. 11, such that the description of the operation of the sense amplifier 152 is not repeated here.

If a programmed high resistance is being read from the selected bit cell 190 and leakage currents of the unselected bit cells 190 are large, the total sensed current may surpass a read 1 margin of the sense amplifier 152, resulting in a read 1 error. However, with each of the bit cells 190 including an FBI GAA MOSFET 82, the leakage current of the unselected bit cells 190 is reduced and the sense amplifier 152 does not provide a read 1 error. Advantages of using the FBI GAA MOSFET 82 in the bit cells 190 include a reduction in the off current Ioff, i.e., a reduction in the leakage current, of a bit cell 190, an increased read 1 margin, and improved operations at minimum power voltages, such as VDDmin.

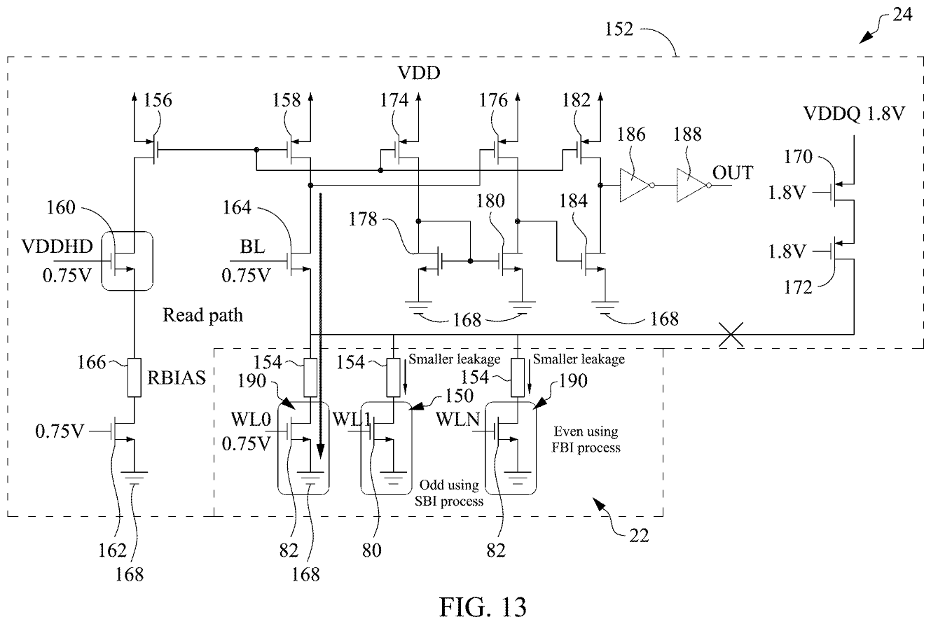

FIG. 13 is a diagram schematically illustrating a bit cell memory array 22 that includes bit cells 150 and 190 electrically connected to the sense amplifier 152, in accordance with some embodiments. The bit cells 150 each include an SBI GAA MOSFET 80 of FIG. 7 coupled to the sense amplifier 152 and the bit cells 190 each include an FBI GAA MOSFET 82 of FIG. 8 coupled to the sense amplifier 152. The bit cells 190 are used as even numbered bit cells and the bit cells 150 are used as odd numbered bit cells.

Each of the bit cells 150 includes an SBI GAA MOSFET 80 electrically connected to an eFuse memory element 154 that is electrically connected to the sense amplifier 152, and each of the bit cells 190 includes an FBI GAA MOSFET 82 electrically connected to an eFuse memory element 154 that is electrically connected to the sense amplifier 152. The sense amplifier 152 includes n-channel and p-channel GAA MOSFETS like GAA MOSFET 50 of FIGS. 3, 4, and 5, which have the drain/source regions 52a and 52b that extend into the substrate 54. The bit cells 150 and 190 are part of the bit cell memory array 22 and the sense amplifier 152 is part of the sensing circuit 24 in the semiconductor device 20 of FIG. 1. In some embodiments, the eFuse memory element 154 is a metal fuse link.

One end of each eFuse memory element 154 is electrically connected to the drain/source region of the third n-channel MOSFET 164 and the other end of the eFuse memory element 154 is connected to either one drain/source region of the SBI GAA MOSFET 80 or to one drain/source region of the FBI GAA MOSFET 82. The other drain/source regions of the SBI GAA MOSFET 80 and the FBI GAA MOSFET 82 are electrically connected to the reference 168.

The sense amplifier 152 is like the sense amplifier 152 shown in FIG. 11, such that the description of the sense amplifier 152 is not repeated here. Also, the sense amplifier 152 operates to read the state of one of the bit cells 150 and 190 as described in relation to the sense amplifier 152 and the bit cells 150 shown in FIG. 11, such that the description of the operation of the sense amplifier 152 is not repeated here.

If a programmed high resistance is being read from a selected bit cell 150 or 190 and leakage currents of the unselected bit cells 150 and 190 are large, the total sensed current may surpass a read 1 margin of the sense amplifier 152, resulting in a read 1 error. However, with each of the bit cells 150 and 190 including an SBI GAA MOSFET 80 or an FBI GAA MOSFET 82, the leakage current of the unselected bit cells 150 and 190 is reduced and the sense amplifier 152 does not provide a read 1 error. Advantages of using the SBI GAA MOSFET 80 and the FBI GAA MOSFET 82 in the bit cells 150 and 190 include a reduction in the off current Ioff, i.e., a reduction in the leakage current, an increased read 1 margin, and improved operations at minimum power voltages, such as VDDmin.

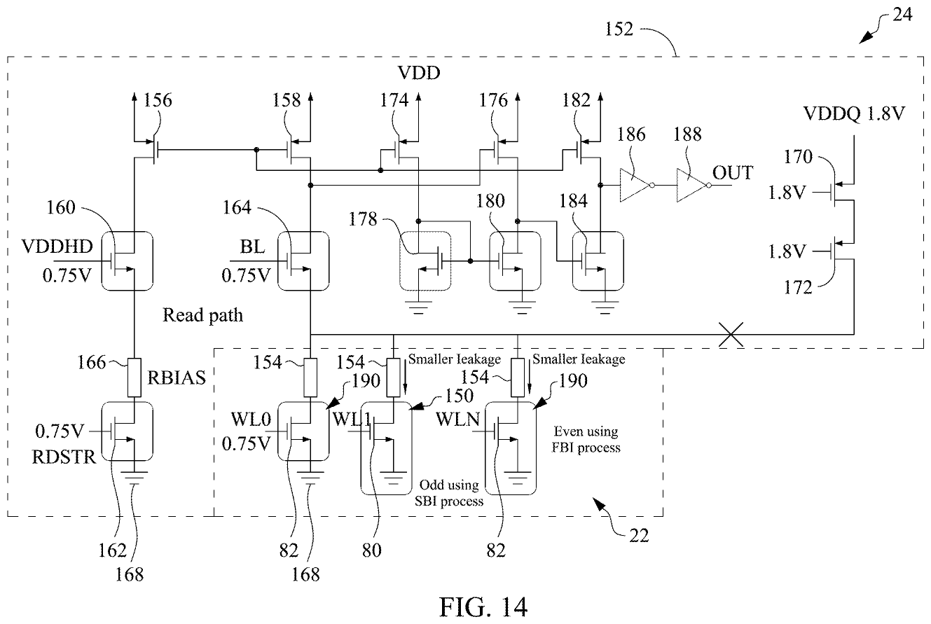

FIG. 14 is a diagram schematically illustrating a bit cell memory array 22 that includes bit cells 150 and 190 electrically connected to a sense amplifier 152 that includes n-channel GAA MOSFETs 160, 162, 164, 178, 180, and 184 that are each either an SBI GAA MOSFET 80 or an FBI GAA MOSFET 82, in accordance with some embodiments. The bit cells 150 each include an SBI GAA MOSFET 80 of FIG. 7 coupled to the sense amplifier 152 and the bit cells 190 each include an FBI GAA MOSFET 82 of FIG. 8 coupled to the sense amplifier 152. The bit cells 190 are used as even numbered bit cells and the bit cells 150 are used as odd numbered bit cells. In other embodiments, the bit cells 190 and the bit cells 150 are used in another order.

Each of the bit cells 150 includes an SBI GAA MOSFET 80 electrically connected to an eFuse memory element 154 that is electrically connected to the sense amplifier 152, and each of the bit cells 190 includes an FBI GAA MOSFET 82 electrically connected to an eFuse memory element 154 that is electrically connected to the sense amplifier 152. The sense amplifier 152 includes p-channel GAA MOSFETS like GAA MOSFET 50 of FIGS. 3, 4, and 5, which have the drain/source regions 52a and 52b that extend into the substrate 54, and n-channel GAA MOSFETs 160, 162, 164, 178, 180, and 184 that are each either an SBI GAA MOSFET 80 or an FBI GAA MOSFET 82. The bit cells 150 and 190 are part of the bit cell memory array 22 and the sense amplifier 152 is part of the sensing circuit 24 in the semiconductor device 20 of FIG. 1. In some embodiments, the eFuse memory element 154 is a metal fuse link.

One end of each eFuse memory element 154 is electrically connected to the drain/source region of the third n-channel MOSFET 164 and the other end of the eFuse memory element 154 is connected to either one drain/source region of the SBI GAA MOSFET 80 or to one drain/source region of the FBI GAA MOSFET 82. The other drain/source regions of the SBI GAA MOSFET 80 and the FBI GAA MOSFET 82 are electrically connected to the reference 168.

The sense amplifier 152 is like the sense amplifier 152 shown in FIG. 11, with the exception that the n-channel GAA MOSFETs 160, 162, 164, 178, 180, and 184 are each either an SBI GAA MOSFET 80 or an FBI GAA MOSFET 82, such that the description of the sense amplifier 152 is not repeated here. Also, the sense amplifier 152 operates to read the state of one of the bit cells 150 and 190 as described in relation to the sense amplifier 152 and the bit cells 150 shown in FIG. 11, such that the description of the operation of the sense amplifier 152 is not repeated here.

If a programmed high resistance is being read from a selected bit cell 150 or 190 and leakage currents of the unselected bit cells 150 and 190 are large, the total sensed current may surpass a read 1 margin of the sense amplifier 152, resulting in a read 1 error. However, with each of the bit cells 150 and 190 including an SBI GAA MOSFET 80 or an FBI GAA MOSFET 82, the leakage current of the unselected bit cells 150 and 190 is reduced and the sense amplifier 152 does not provide a read 1 error. Advantages of using the SBI GAA MOSFET 80 and the FBI GAA MOSFET 82 in the bit cells 150 and 190 include a reduction in the off current Ioff, i.e., a reduction in the leakage current, an increased read 1 margin, and improved operations at minimum power voltages, such as VDDmin.

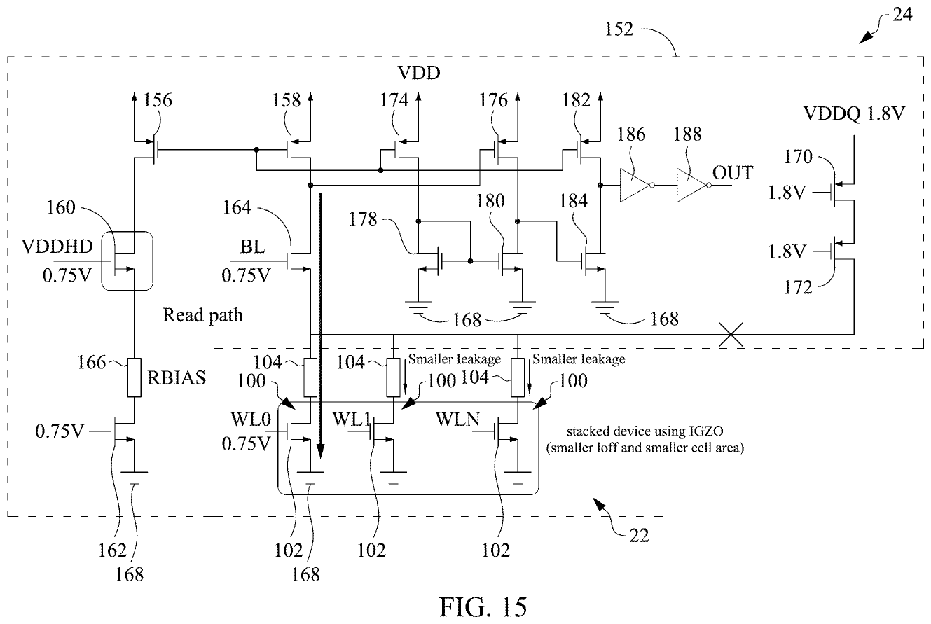

FIG. 15 is a diagram schematically illustrating stacked IGZO device bit cells 100 coupled to the sense amplifier 152, in accordance with some embodiments. Each of the bit cells 100 includes an IGZO transistor 102 electrically connected to an eFuse memory element 104 that is electrically connected to the sense amplifier 152. The sense amplifier 152 includes n-channel and p-channel GAA MOSFETS like GAA MOSFET 50 of FIGS. 3, 4, and 5, which have the drain/source regions 52a and 52b that extend into the substrate 54. The bit cells 100 are part of the bit cell memory array 22 and the sense amplifier 152 is part of the sensing circuit 24 in the semiconductor device 20 of FIG. 1. In some embodiments, the eFuse memory element 104 is a metal fuse link.

The bit cell memory array 22 includes the bit cells 100. Each of the bit cells 100 includes an IGZO transistor 102 electrically connected to an eFuse memory element 104 that is electrically connected to the sense amplifier 152. One end of each eFuse memory element 104 is electrically connected to the drain/source region of the third n-channel MOSFET 164 and the other end of the eFuse memory element 104 is connected to one drain/source region of an IGZO transistor 102. The other drain/source region of the IGZO transistor 102 is electrically connected to the reference 168.

The sense amplifier 152 is like the sense amplifier 152 shown in FIG. 11, such that the description of the sense amplifier 152 is not repeated here. Also, the sense amplifier 152 operates to read the state of one of the bit cells 100 as described in relation to the sense amplifier 152 and the bit cells 150 shown in FIG. 11, such that the description of the operation of the sense amplifier 152 is not repeated here.

If a programmed high resistance is being read from the selected bit cell 100 and leakage currents of the unselected bit cells 100 are large, the total sensed current may surpass a read 1 margin of the sense amplifier 152, resulting in a read 1 error. However, with each of the bit cells 100 including an IGZO transistor 102, the leakage current of the unselected bit cells 100 is reduced and the sense amplifier 152 does not provide a read 1 error. Advantages of using the IGZO transistor 102 in the bit cells 100 include a reduction in the off current Ioff, i.e., a reduction in the leakage current, of a bit cell 100, an increased read 1 margin, and improved operations at minimum power voltages, such as VDDmin. Also, using stacked IGZO device bit cells 100 in a stacked memory configuration reduces the area consumed on the semiconductor device, such that the stacked memory device is a high-density memory.

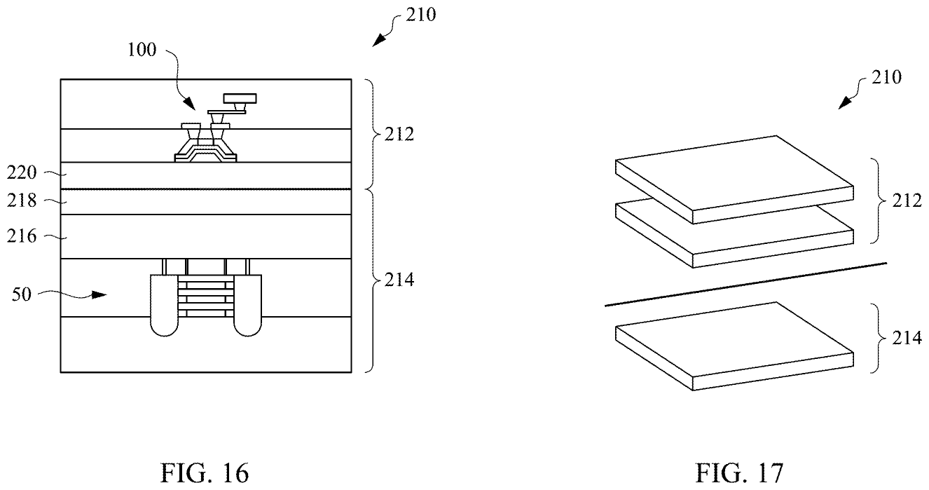

FIG. 16 is a diagram schematically illustrating a high-density memory device 210, in accordance with some embodiments. The high-density memory device 210 includes bit cells 212 situated above peripheral circuitry 214 like the sensing circuit 24 shown in FIG. 1 that includes the sense amplifiers. The bit cells 212 each include the stacked IGZO device 100 of FIG. 10 situated above the peripheral circuitry 214 that includes the GAA MOSFETs 50 of FIGS. 3, 4, and/or 5. In the manufacturing process of the high-density memory device 210, the peripheral circuitry 214 and the bit cells 212 are manufactured in consecutive process steps, one layer on top of another layer. In some embodiments, the peripheral circuitry 214 is like the peripheral circuitry 46 shown in FIG. 2. In some embodiments, the high-density memory device 210 is part of the semiconductor device 20 of FIG. 1 and/or of FIG. 2. In other embodiments, in the manufacturing process of the high-density memory device 210, the peripheral circuitry 214 and the bit cells 212 are manufactured separately and then bonded together.

The high-density memory device 210 includes back-end-of-line (BEOL) routing 216 that is formed above the GAA MOSFET 50 and electrically connected to the GAA MOSFET 50. The GAA MOSFET 50 and the BEOL routing 216 are formed layer by layer. The BEOL routing 216 is electrically connected to the GAA MOSFET 50, such as through via interconnects. A first oxide layer 218 is deposited over the BEOL routing 216 and, in some embodiments, a second oxide layer 220 is deposited on the first oxide layer 218. Also, in some embodiments, only one oxide layer, such as oxide layer 218 or oxide layer 220 is formed over the BEOL routing 216 and under the IGZO device 100 and, in some embodiments, the oxide layers 218 and 220 are combined to form a single oxide layer over the BEOL routing 216 and under the IGZO device 100. The stacked IGZO device 100 is formed layer by layer on the first and/or second oxide layers 218 and 220. Where, the GAA MOSFET 50 and the IGZO device 100 are electrically connected through the first and/or second oxide layers 218 and 220, such as by via interconnects.

FIG. 17 is a diagram schematically illustrating a layout of the high-density memory device 210, in accordance with some embodiments. The layout includes the bit cells 212 situated above the peripheral circuitry 214. The bit cells 212 include the stacked IGZO devices 100 of FIG. 10 situated above the peripheral circuitry 214 that includes the GAA MOSFETs 50 of FIGS. 3, 4, and/or 5.

The bit cells 212 are situated in a different plane of the semiconductor device 20 than the peripheral circuitry 214, where the different plane is above the peripheral circuitry 214. By stacking the bit cells 212 above the peripheral circuitry 214, the density of the memory is increased for the high-density memory device 210, where the area consumed by the high-density memory device 210 is 50% of the area consumed by a planar semiconductor device.

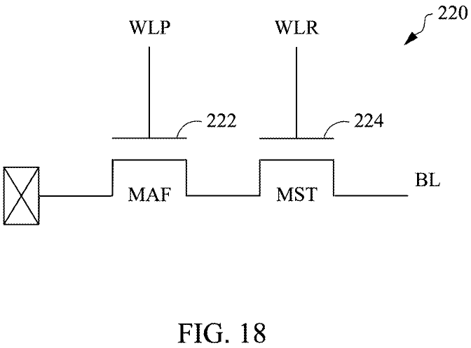

FIG. 18 is a diagram schematically illustrating a two transistor anti-fuse bit cell 220, in accordance with some embodiments. The anti-fuse bit cell 220 includes a first n-channel MOSFET 222 and a second n-channel MOSFET 224. One drain/source region of the first n-channel MOSFET 222 is electrically connected to a source(S) and the other drain/source region of the first n-channel MOSFET 222 is electrically connected to one drain/source region of the second n-channel MOSFET 224. The other drain/source region of the second n-channel MOSFET 224 is electrically connected to a bit line (BL). The first n-channel MOSFET 222 is referred to as the anti-fuse transistor (MAF) and the second n-channel MOSFET 224 is referred to as the select transistor (MST). The gate of the first n-channel MOSFET 222 receives a word-line for programming (WLP) signal and the gate of the second n-channel MOSFET 224 receives a word-line for reading (WLR) signal. In some embodiments, the bit cell memory array 22 of the semiconductor device 20 of FIG. 1 includes anti-fuse bit cells 220.

In operation, to program a selected anti-fuse bit cell 220, a program high voltage (PHV) is provided in the WLP signal and oxide breakdown occurs after energy accumulation. The PHV is usually higher than the I/O supply voltage. To protect the second n-channel MOSFET 224 from being stressed by the subsequent high voltage induced by the programmed oxide, the WLR signal is connected to the I/O supply voltage to reduce the drain-to-gate voltage. Bit cells to be programmed have the BL connected to ground, which is passed to the source of the first n-channel MOSFET 222 to provide enough gate-to-source voltage difference for programming. Unselected bit cells 220 have the WLP signal and the WLR signal connected to ground and the BL connected to the I/O supply voltage to prevent the unselected bit cells 220 from being programmed.

To read a selected anti-fuse bit cell 220, the WLP signal is driven to a read voltage (RV) and the WLR signal is connected to VDD. For programmed bit cells 220, current flows through the conductive connection of the programmed gate oxide to the second n-channel MOSFET 224 and the BL. The unprogrammed bit cells 220 will not conduct current. Also, for a programed bit cell 220, the gate oxide breakdown position near the channel region creates a higher potential barrier between the gate oxide breakdown region and the channel, such that the RV needs to be higher than VDD to overcome this potential barrier.

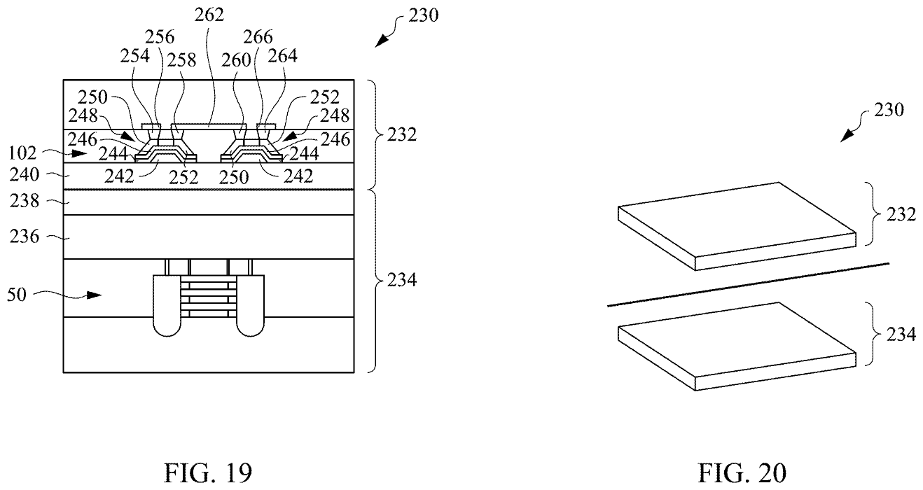

FIG. 19 is a diagram schematically illustrating a high-density memory device 230, in accordance with some embodiments. The high-density memory device 230 includes two transistor anti-fuse bit cells 232 situated above peripheral circuitry 234 like the sensing circuit 24 shown in FIG. 1 that includes the sense amplifiers. Each of the anti-fuse bit cells 232 includes two IGZO transistors 102, shown in FIG. 10, situated above the peripheral circuitry 234 that includes the GAA MOSFETs 50 of FIGS. 3, 4, and/or 5. In the manufacturing process of the high-density memory device 230, the peripheral circuitry 234 and the anti-fuse bit cells 232 are manufactured in consecutive process steps, one layer on top of another layer. In some embodiments, the peripheral circuitry 234 is like the peripheral circuitry 46 shown in FIG. 2. In some embodiments, the high-density memory device 230 is part of the semiconductor device 20 of FIG. 1 and/or of FIG. 2. In other embodiments, in the manufacturing process of the high-density memory device 230, the peripheral circuitry 234 and the anti-fuse bit cells 232 are manufactured separately and then bonded together.

The high-density memory device 230 includes BEOL routing 236 that is formed above the GAA MOSFET 50 and electrically connected to the GAA MOSFET 50. The GAA MOSFET 50 and the BEOL routing 236 are formed layer by layer. The BEOL routing 236 is electrically connected to the GAA MOSFET 50, such as through via interconnects. A first oxide layer 238 is deposited over the BEOL routing 236 and, in some embodiments, a second oxide layer 240 is formed on the first oxide layer 238. Also, in some embodiments, only one oxide layer, such as oxide layer 238 or oxide layer 240 is formed over the BEOL routing 236 and under the two transistor anti-fuse bit cells 232 and, in some embodiments, the oxide layers 238 and 240 are combined to form a single oxide layer over the BEOL routing 236 and under the two transistor anti-fuse bit cells 232. The two transistor anti-fuse bit cells 232 are formed layer by layer on the first and/or second oxide layer 238 and 240. Each of the two transistor anti-fuse bit cells 232 is like the two transistor anti-fuse bit cell 220 of FIG. 18, such that the two transistor anti-fuse bit cell 232 is connected like and operates like the two transistor anti-fuse bit cell 220 of FIG. 18. Also, the GAA MOSFET 50 and the two transistor anti-fuse bit cells 232 are electrically connected through the first and/or second oxide layers 238 and 240, such as by via interconnects.

Each of the anti-fuse bit cells 232 includes two IGZO transistors 102 electrically connected to each other. Each of the IGZO transistors 102 includes a TiN gate 242 deposited on the second oxide layer 240. A high-k dielectric 244, such as HfO2, is deposited on the TiN gate 242, and an IGZO active region 246 is deposited on the high-k dielectric 244. A TiN layer 248 is deposited and patterned on the IGZO active region 246 to form drain/source regions 250 and 252. One of the drain/source regions 250 is electrically connected to a via 254 and a metal layer segment 256. Another drain/source region 252 is electrically connected to the drain/source region 250 of the other IGZO transistor 102 through via 258 and 260 and a metal layer segment 262. The other drain/source region 252 is electrically connected to a via 264 and a metal layer segment 266.

In operation, each of the anti-fuse bit cells 232 operates like the anti-fuse bit cell 220 of FIG. 18. Advantages of the anti-fuse bit cell 232 include a reduction in off current Ioff, i.e., a reduction in leakage current, an increased read margin, and a smaller area of the high-density memory device 230.

FIG. 20 is a diagram schematically illustrating a layout of the high-density memory device 230, in accordance with some embodiments. The layout includes the anti-fuse bit cells 232 situated above the peripheral circuitry 234. Each of the anti-fuse bit cells 232 includes two IGZO transistors 102 shown in FIG. 10 situated above the peripheral circuitry 234 that is manufactured using the GAA MOSFETs 50 of FIGS. 3, 4, and/or 5.

The anti-fuse bit cells 232 are situated in a different plane of the semiconductor device 20 than the peripheral circuitry 234, where the different plane is above the peripheral circuitry 234. By stacking the bit cells 232 above the peripheral circuitry 234, the density of the memory is increased for the high-density memory device 230, where the area consumed by the high-density memory device 230 is 50% of the area consumed by a planar semiconductor device.

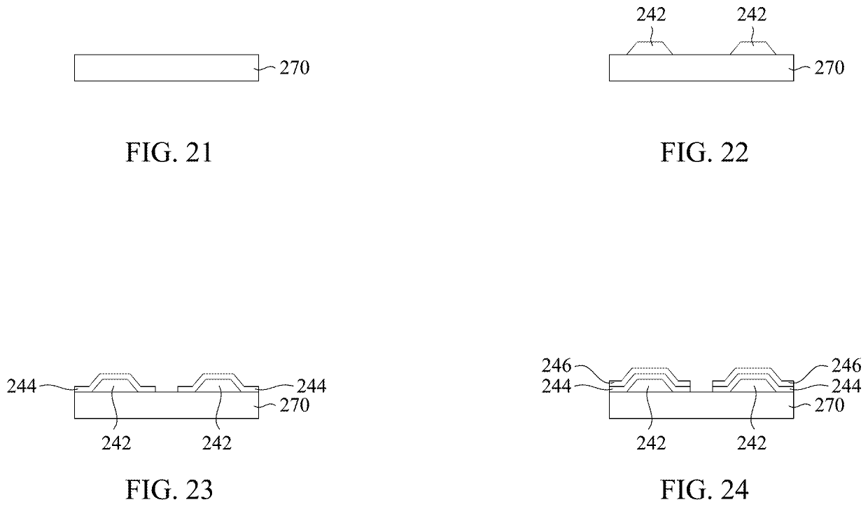

FIGS. 21-28 are diagrams schematically illustrating a manufacturing process for manufacturing IGZO transistors, such as IGZO transistors 102 shown in FIG. 10, in accordance with some embodiments. In some embodiments, the manufacturing process is for manufacturing BEOL thin film IGZO transistors.

FIG. 21 is a diagram schematically illustrating the deposition of an oxide layer 270 in a semiconductor device, such as the semiconductor device 20 of FIG. 1 and/or of FIG. 2, in accordance with some embodiments. In some embodiments, the oxide layer 270 is like the oxide layer 108 shown in FIG. 10. In some embodiments the oxide layer 270 is like the second oxide layer 240 shown in FIG. 19.

FIG. 22 is a diagram schematically illustrating a TiN deposition and photo patterning of the TiN deposition to form two TiN gates 242 on the oxide layer 270, in accordance with some embodiments.

FIG. 23 is a diagram schematically illustrating a high-k dielectric deposition and photo patterning of the high-k dielectric 244 on the TiN gates 242, in accordance with some embodiments. In some embodiments, the high-k dielectric 244 is HfO2.

FIG. 24 is a diagram schematically illustrating an IGZO active region deposition and photo patterning to provide the IGZO active region 246 deposited on the high-k dielectric 244, in accordance with some embodiments.

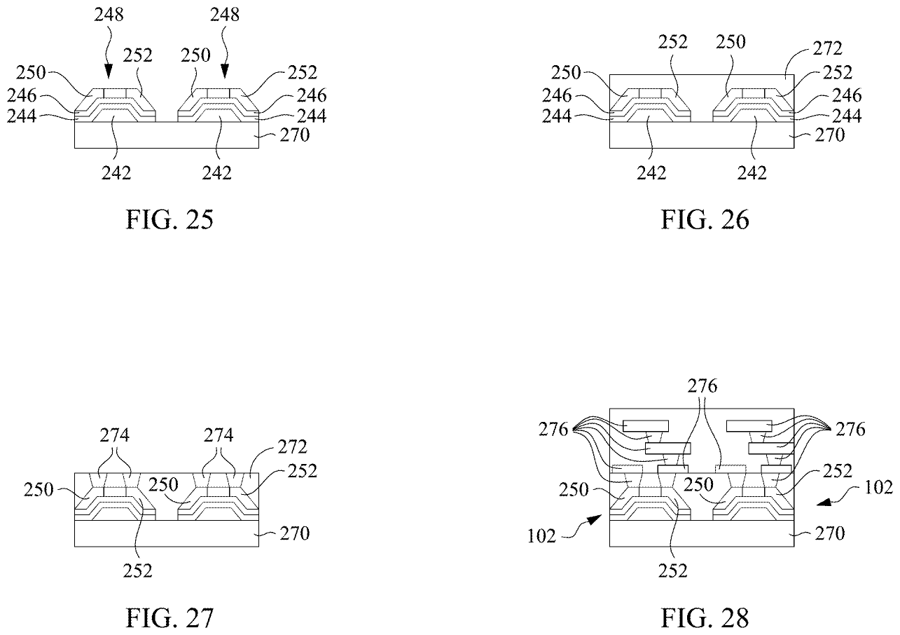

FIG. 25 is a diagram schematically illustrating a TiN layer deposition and photo patterning to form drain/source regions 250 and 252 in the Tin layer 248, in accordance with some embodiments. The TiN layer 248 is deposited and photo patterned on the IGZO active region 246 to form the drain/source regions 250 and 252.

FIG. 26 is a diagram schematically illustrating an oxide layer 272 deposition, in accordance with some embodiments. FIG. 27 is a diagram schematically illustrating contact etching through the oxide layer 272 to provide via holes 274 to the drain/source regions 250 and 252, in accordance with some embodiments.

FIG. 28 is a diagram schematically illustrating conductive routing 276, such as via and metal layer routing to contact the drain/source regions 250 and 252 of the IGZO transistors 102.

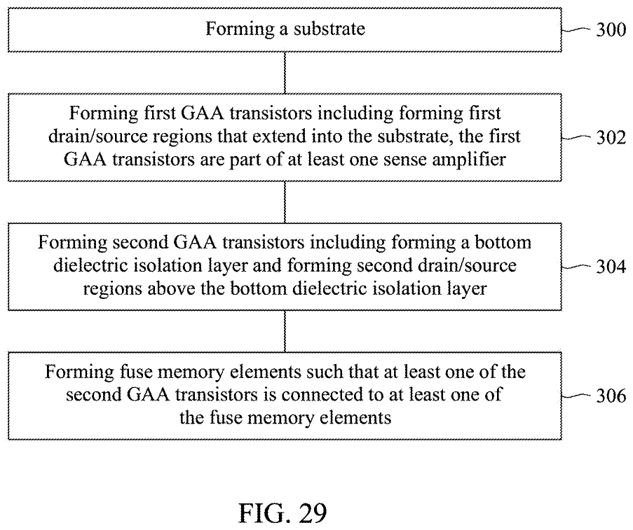

FIG. 29 is a diagram schematically illustrating a method of manufacturing a semiconductor device, in accordance with some embodiments. At 300, the method includes forming a substrate, such as substrate 54 (shown in FIGS. 3-5), and, at 302, the method includes forming first GAA transistors, such as GAA MOSFET 50, including forming first drain/source regions, such as drain/source regions 52a and 52b, that extend into the substrate, where the first GAA transistors are part of at least one sense amplifier, such as sense amplifier 152 of FIGS. 11-15.

At 304, the method includes forming second GAA transistors, such as GAA MOSFETS 80 and 82 of FIGS. 7 and 8, respectively, including forming a bottom dielectric isolation layer, such as bottom dielectric layer 86, and 86a and 86b, and forming second drain/source regions, such as drain/source regions 88a and 88b, above the bottom dielectric isolation layer. In some embodiments, forming the second GAA transistors includes forming the second drain/source regions in contact with the bottom dielectric isolation layer. In some embodiments, forming the second GAA transistors includes forming one of the second drain/source regions, such as drain/source region 88a, above a first segment of the bottom dielectric isolation layer, such as bottom dielectric layer 86a, and forming another one of the second drain/source regions, such as drain/source region 88b, above a second segment of the bottom dielectric isolation layer, such as bottom dielectric layer 86b. In some embodiments, forming the second GAA transistors includes forming one of the second drain/source regions, such as drain/source region 88a, and another one of the second drain/source regions, such as drain/source region 88b, above a segment of the bottom dielectric isolation layer, such as bottom dielectric layer 86, that extends from the one of the second drain/source regions to the other one of the second drain/source regions. In some embodiments, forming the second GAA transistors includes forming a first one of the second drain/source regions, such as drain/source region 88a, above a first segment of the bottom dielectric isolation layer, such as bottom dielectric layer 86a, and forming a second one of the second drain/source regions, such as drain/source region 88b, above a second segment of the bottom dielectric isolation layer, such as bottom dielectric layer 86b, and forming a third one of the second drain/source regions, such as drain/source region 88a, and a fourth one of the second drain/source regions, such as drain/source region 88b, above a third segment of the bottom dielectric isolation layer, such as bottom dielectric layer 86, that extends from the third one of the second drain/source regions to the fourth one of the second drain/source regions.

At 306, the method includes forming fuse memory elements, such as fuse memory elements 72 and 154, such that at least one of the second GAA transistors is connected to at least one of the fuse memory elements.

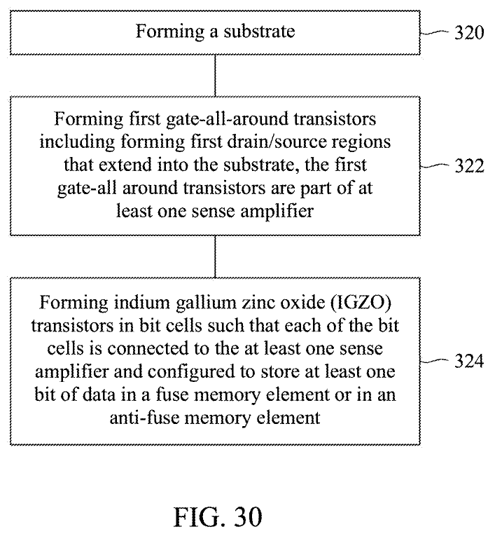

FIG. 30 is a diagram schematically illustrating another method of manufacturing a semiconductor device, such as semiconductor device 210, in accordance with some embodiments. At 320, the method includes forming a substrate, such as substrate 54 (shown in FIGS. 3-5).

At 322, the method includes forming first GAA transistors, such as GAA MOSFET 50, including forming first drain/source regions, such as drain/source regions 52a and 52b, that extend into the substrate, where the first GAA transistors are part of at least one sense amplifier, such as sense amplifier 152 of FIGS. 11-15. In some embodiments, forming the first GAA transistors includes forming the first GAA transistors on a first plane, such as in peripheral circuitry 214 (shown in FIG. 17), of the semiconductor device and forming IGZO transistors on at least one second plane, such as bit cells 212 or bit cells 232, of the semiconductor device that is different than the first plane of the semiconductor device. In some embodiments, the at least one second plane is situated directly above the first plane.

At 324, the method includes forming IGZO transistors, such as IGZO transistor 102, in bit cells, such as bit cells 212 and 232, such that each of the bit cells is connected to the at least one sense amplifier, such as sense amplifier 152 of FIGS. 11-15, and configured to store at least one bit of data in a fuse memory element, such as eFuse memory element 104, or in an anti-fuse memory element such as in bit cell 232. In some embodiments, forming IGZO transistors includes forming at least two IGZO transistors connected in series to provide the anti-fuse memory element.

In some embodiments, the method includes forming fuse memory elements, such as eFuse memory element 104, such that each of the IGZO transistors, such as IGZO transistor 102, is connected to one of the fuse memory elements. In some embodiments, the method includes forming second GAA transistors, such as GAA MOSFETS 80 and 82 of FIGS. 7 and 8, respectively, which includes forming a bottom dielectric isolation layer, such as bottom dielectric layer 86, and 86a and 86b, and forming second drain/source regions, such as drain/source regions 88a and 88b, on the bottom dielectric isolation layer, where the second GAA transistors are part of the at least one sense amplifier, such as sense amplifier 152 of FIGS. 11-15.

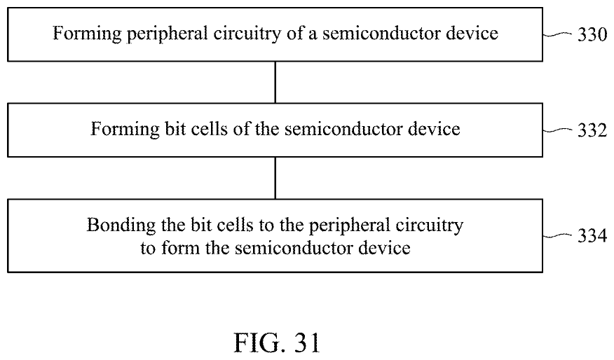

FIG. 31 is a diagram schematically illustrating an alternative method of manufacturing a semiconductor device, such as semiconductor device 210 or semiconductor device 230, in accordance with some embodiments.

At 330, the method includes forming peripheral circuitry, such as peripheral circuitry 214 and peripheral circuitry 234, of the semiconductor device. The method includes forming a substrate, such as substrate 54 (shown in FIGS. 3-5) and forming first GAA transistors, such as GAA MOSFET 50, including forming first drain/source regions, such as drain/source regions 52a and 52b, that extend into the substrate, where the first GAA transistors are part of at least one sense amplifier, such as sense amplifier 152 of FIGS. 11-15. In some embodiments, forming the peripheral circuitry includes forming the first GAA transistors on a first plane, such as in the peripheral circuitry 214 or the peripheral circuitry 234 of the semiconductor device.

At 332, the method includes forming bit cells, such as bit cells 212 and 232, of the semiconductor device. The method includes forming IGZO transistors, such as IGZO transistor 102, in the bit cells, where the bit cells are configured to store at least one bit of data in a fuse memory element, such as eFuse memory element 104, or in an anti-fuse memory element such as in bit cell 232. In some embodiments, forming bit cells includes forming at least two IGZO transistors connected in series to provide the anti-fuse memory element.

At 334, the method includes bonding the bit cells formed in step 332 to the peripheral circuitry formed in step 330 to form the semiconductor device. The peripheral circuitry is formed on a first plane and the IGZO transistors are formed on a second plane that is different than the first plane. The first and second planes are bonded together to form the semiconductor device. In some embodiments, the second plane is situated directly above the first plane. In some embodiments, the second plane is situated directly above the first plane, such that each of the bit cells is connected to at least one sense amplifier, such as sense amplifier 152 of FIGS. 11-15.

In some embodiments, the method includes forming fuse memory elements, such as eFuse memory element 104, such that each of the IGZO transistors, such as IGZO transistor 102, is connected to one of the fuse memory elements. In some embodiments, the method includes forming second GAA transistors, such as GAA MOSFETS 80 and 82 of FIGS. 7 and 8, respectively, which includes forming a bottom dielectric isolation layer, such as bottom dielectric layer 86, and 86a and 86b, and forming second drain/source regions, such as drain/source regions 88a and 88b, on the bottom dielectric isolation layer, where the second GAA transistors are part of the at least one sense amplifier, such as sense amplifier 152 of FIGS. 11-15.

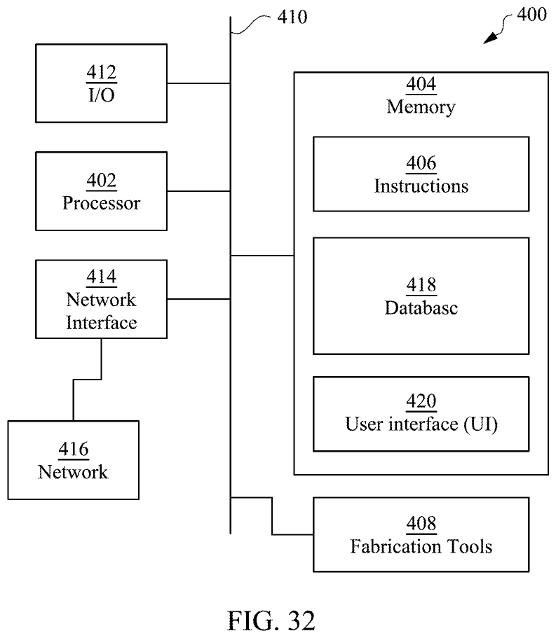

FIG. 32 is a block diagram schematically illustrating an example of a computer system 400 configured to provide the semiconductor devices and methods of the current disclosure, in accordance with some embodiments. Some or all the design, layout, and manufacture of the semiconductor devices, also referred to as semiconductor circuits, can be performed by or with the computer system 400. In some embodiments, the computer system 400 includes an electronic design automation (EDA) system. In some embodiments, the semiconductor devices are ICs.

In some embodiments, the system 400 is a general-purpose computing device including a processor 402 and a non-transitory, computer-readable storage medium 404. The computer-readable storage medium 404 may be encoded with, e.g., store, computer program code such as executable instructions 406. Execution of the instructions 406 by the processor 402 provides (at least in part) a design tool that implements a portion or all the functions of the system 400, such as pre-layout simulations, post-layout simulations, routing, rerouting, and final layout for manufacturing. Further, fabrication tools 408 are included to further layout and physically implement the design and manufacture of the semiconductor devices. In some embodiments, execution of the instructions 406 by the processor 402 provides (at least in part) a design tool that implements a portion or all the functions of the system 400. In some embodiments, the system 400 includes a commercial router. In some embodiments, the system 400 includes an automatic place and route (APR) system.

The processor 402 is electrically coupled to the computer-readable storage medium 404 by a bus 410 and to an I/O interface 412 by the bus 410. A network interface 414 is also electrically connected to the processor 402 by the bus 410. The network interface 414 is connected to a network 416, so that the processor 402 and the computer-readable storage medium 404 can connect to external elements using the network 416. The processor 402 is configured to execute the computer program code or instructions 406 encoded in the computer-readable storage medium 404 to cause the system 400 to perform a portion or all the functions of the system 400, such as providing the semiconductor devices and methods of the current disclosure and other functions of the system 400. In some embodiments, the processor 402 is a central processing unit (CPU), a multi-processor, a distributed processing system, an application specific integrated circuit (ASIC), and/or a suitable processing unit.

In some embodiments, the computer-readable storage medium 404 is an electronic, magnetic, optical, electromagnetic, infrared, and/or semiconductor system or apparatus or device. For example, the computer-readable storage medium 404 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 404 can include a compact disk read only memory (CD-ROM), a compact disk read/write memory (CD-R/W), and/or a digital video disc (DVD).

In some embodiments, the computer-readable storage medium 404 stores computer program code or instructions 406 configured to cause the system 400 to perform a portion or all the functions of the system 400. In some embodiments, the computer-readable storage medium 404 also stores information which facilitates performing a portion or all the functions of the system 400. In some embodiments, the computer-readable storage medium 404 stores a database 418 that includes one or more of component libraries, digital circuit cell libraries, and databases.

The system 400 includes the I/O interface 412, which is coupled to external circuitry. In some embodiments, the I/O interface 412 includes a keyboard, keypad, mouse, trackball, trackpad, touchscreen, and/or cursor direction keys for communicating information and commands to the processor 402.

The network interface 414 is coupled to the processor 402 and allows the system 400 to communicate with the network 416, to which one or more other computer systems are connected. The network interface 414 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 400 can be performed in two or more systems that are like system 400.

The system 400 is configured to receive information through the I/O interface 412. The information received through the I/O interface 412 includes one or more of instructions, data, design rules, libraries of components and cells, and/or other parameters for processing by the processor 402. The information is transferred to the processor 402 by the bus 410. Also, the system 400 is configured to receive information related to a user interface (UI) through the I/O interface 412. This UI information can be stored in the computer-readable storage medium 404 as a UI 420.

In some embodiments, a portion or all the functions of the system 400 are implemented via a standalone software application for execution by a processor. In some embodiments, a portion or all the functions of the system 400 are implemented in a software application that is a part of an additional software application. In some embodiments, a portion or all the functions of the system 400 are implemented as a plug-in to a software application. In some embodiments, at least one of the functions of the system 400 is implemented as a software application that is a portion of an EDA tool. In some embodiments, a portion or all the functions of the system 400 are implemented as a software application that is used by the system 400. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 400 include fabrication tools 408 for implementing the manufacturing processes of the system 400. For example, based on the final layout, photolithographic masks may be generated, which are used to fabricate the semiconductor device by the fabrication tools 408.

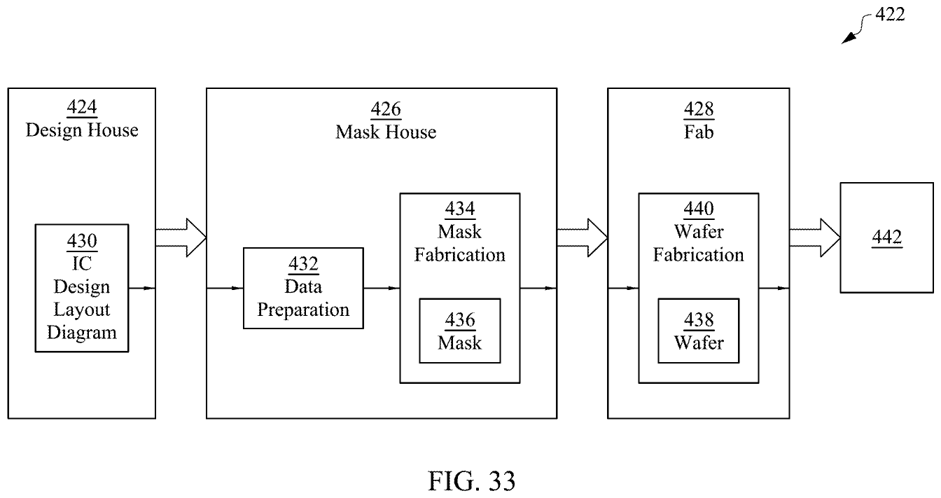

Further aspects of device fabrication are disclosed in conjunction with FIG. 33, which is a block diagram of a semiconductor device manufacturing system 422 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 422.

In FIG. 33, the semiconductor device manufacturing system 422 includes entities, such as a design house 424, a mask house 426, and a semiconductor device manufacturer/fabricator (“Fab”) 428, that interact with one another in the design, development, and manufacturing cycles and/or services related to manufacturing a semiconductor device, such as the semiconductor devices described herein. The entities in the system 422 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 424, the mask house 426, and the semiconductor device fab 428 are owned by a single larger company. In some embodiments, two or more of the design house 424, the mask house 426, and the semiconductor device fab 428 coexist in a common facility and use common resources.

The design house (or design team) 424 generates a semiconductor device design layout diagram 430. The semiconductor device design layout diagram 430 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 430 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 424 implements a design procedure to form a semiconductor device design layout diagram 430. The semiconductor device design layout diagram 430 is presented in one or more data files having information of the geometrical patterns. For example, semiconductor device design layout diagram 430 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 426 includes data preparation 432 and mask fabrication 434. The mask house 426 uses the semiconductor device design layout diagram 430 to manufacture one or more masks 436 to be used for fabricating the various layers of the semiconductor device or semiconductor structure. The mask house 426 performs mask data preparation 432, where the semiconductor device design layout diagram 430 is translated into a representative data file (RDF). The mask data preparation 432 provides the RDF to the mask fabrication 434. The mask fabrication 434 includes a mask writer that converts the RDF to an image on a substrate, such as a mask (reticle) 436 or a semiconductor wafer 438. The design layout diagram 430 is manipulated by the mask data preparation 432 to comply with characteristics of the mask writer and/or criteria of the semiconductor device fab 428. In FIG. 33, the mask data preparation 432 and the mask fabrication 434 are illustrated as separate elements. In some embodiments, the mask data preparation 432 and the mask fabrication 434 can be collectively referred to as mask data preparation.

In some embodiments, the mask data preparation 432 includes an optical proximity correction (OPC) which uses lithography enhancement techniques to compensate for image errors, such as those that can arise from diffraction, interference, other process effects and the like. The OPC adjusts the semiconductor device design layout diagram 430. In some embodiments, the mask data preparation 432 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 432 includes a mask rule checker (MRC) that checks the semiconductor device design layout diagram 430 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 430 to compensate for limitations during the mask fabrication 434, which may undo part of the modifications performed by OPC to meet mask creation rules.

In some embodiments, the mask data preparation 432 includes lithography process checking (LPC) that simulates processing that will be implemented by the semiconductor device fab 428. LPC simulates this processing based on the semiconductor device design layout diagram 430 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are to be repeated to further refine the semiconductor device design layout diagram 430.

The above description of mask data preparation 432 has been simplified for the purposes of clarity. In some embodiments, data preparation 432 includes additional features such as a logic operation (LOP) to modify the semiconductor device design layout diagram 430 according to manufacturing rules. Additionally, the processes applied to the semiconductor device design layout diagram 430 during data preparation 432 may be executed in a variety of different orders.

After the mask data preparation 432 and during the mask fabrication 434, a mask 436 or a group of masks 436 are fabricated based on the modified semiconductor device design layout diagram 430. In some embodiments, the mask fabrication 434 includes performing one or more lithographic exposures based on the semiconductor device design layout diagram 430. In some embodiments, an electron-beam (e-beam) or a mechanism of multiple e-beams is used to form a pattern on a mask (photomask or reticle) 436 based on the modified semiconductor device design layout diagram 430. The mask 436 can be formed in various technologies. In some embodiments, the mask 436 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 436 includes a transparent substrate (e.g., fused quartz) and an opaque material (e.g., chromium) coated in the opaque regions of the binary mask. In another example, the mask 436 is formed using a phase shift technology. In a phase shift mask (PSM) version of the mask 436, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 434 is used in a variety of processes. For example, such a mask(s) is used in an ion implantation process to form various doped regions in the semiconductor wafer 438, in an etching process to form various etching regions in the semiconductor wafer 438, and/or in other suitable processes.

The semiconductor device fab 428 includes wafer fabrication 440. The semiconductor device fab 428 is a semiconductor device fabrication business that includes one or more manufacturing facilities for the fabrication of a variety of different semiconductor device products. In some embodiments, the semiconductor device fab 428 is a semiconductor foundry. For example, there may be a manufacturing facility for the front end of line (FEOL) fabrication of a plurality of semiconductor device products, while a second manufacturing facility may provide the BEOL fabrication for the interconnection and packaging of the semiconductor device products, and a third manufacturing facility may provide other services for the foundry business.

The semiconductor device fab 428 uses the mask(s) 436 fabricated by the mask house 426 to fabricate the semiconductor structures or semiconductor devices 442 of the current disclosure. Thus, the semiconductor device fab 428 at least indirectly uses the semiconductor device design layout diagram 430 to fabricate the semiconductor structures or semiconductor devices 442 of the current disclosure. Also, the semiconductor wafer 438 includes a silicon substrate or other proper substrate having material layers formed thereon, and the semiconductor wafer 438 further includes one or more of various doped regions, dielectric features, multilevel interconnects, and the like (formed at subsequent manufacturing steps). In some embodiments, the semiconductor wafer 438 is fabricated by the semiconductor device fab 428 using the mask(s) 436 to form the semiconductor structures or semiconductor devices 442 of the current disclosure. In some embodiments, the semiconductor device fabrication includes performing one or more lithographic exposures based at least indirectly on the semiconductor device design layout diagram 430.

Disclosed embodiments of the present application provide a semiconductor device that has an improved read 1 margin, where the off current Ioff of unselected bits is reduced and the read 1 margin is increased. In some embodiments, the semiconductor device includes bit cells that each have a GAA MOSFET that has a bottom dielectric layer situated under the drain/source regions of the MOSFET, which reduces the off current Ioff of the GAA MOSFET. In some embodiments, the semiconductor device includes bit cells that each include an IGZO device that includes an IGZO transistor, with a reduced off current Ioff, connected to a fuse memory element, such as a metal fuse. In some embodiments, the semiconductor device includes one or more sense amplifiers that include GAA transistors that have drain/source regions that extend into a substrate.

Further disclosed embodiments provide a semiconductor device that includes stacked IGZO devices situated above sense amplifiers in a high-density memory. In some embodiments, the semiconductor device includes a substrate, at least one sense amplifier that includes GAA transistors that have first drain/source regions that extend into the substrate, and bit cells that include IGZO transistors, where each of the bit cells is connected to the at least one sense amplifier and configured to store at least one bit of data in a fuse memory element or in an anti-fuse memory element. In some embodiments, each of the IGZO transistors is connected to a fuse memory element. In some embodiments, each of the bit cells includes at least two IGZO transistors connected in series to provide an anti-fuse bit cell. In some embodiments, each of the bit cells includes more than two IGZO transistors connected to provide a memory element, such as an anti-fuse memory element.

Further disclosed embodiments include semiconductor devices with different layouts or designs and methods of forming the semiconductor devices described herein.

In accordance with some embodiments, a memory device includes a substrate, a sense amplifier that includes first gate-all-around transistors that have first drain/source regions that extend into the substrate, and bit cells that include fuse memory elements and second gate-all-around transistors. Each of the bit cells includes a fuse memory element having a first terminal connected to an input of the sense amplifier and a second terminal connected to a second gate-all-around transistor that includes second drain/source regions and a bottom dielectric isolation layer under the second drain/source regions.

In accordance with further embodiments, a semiconductor device includes a substrate, at least one sense amplifier that includes first GAA transistors that have first drain/source regions that extend into the substrate, and bit cells that include IGZO transistors, each of the bit cells is connected to the at least one sense amplifier and configured to store at least one bit of data in a fuse or an anti-fuse.

In accordance with still further disclosed aspects, a method of manufacturing a semiconductor device includes forming a substrate; forming first GAA transistors including forming first drain/source regions that extend into the substrate, the first GAA transistors are part of at least one sense amplifier; forming second GAA transistors including forming a bottom dielectric isolation layer and forming second drain/source regions above the bottom dielectric isolation layer; and forming fuse memory elements such that at least one of the second GAA transistors is connected to at least one of the fuse memory elements.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a substrate;
a sense amplifier that includes first gate-all-around transistors that have first drain/source regions that extend into the substrate; and
bit cells that include fuse memory elements and second gate-all-around transistors where each of the bit cells includes a fuse memory element having a first terminal connected to an input of the sense amplifier and a second terminal connected to a second gate-all-around transistor that includes second drain/source regions and a bottom dielectric isolation layer under the second drain/source regions.

2. The device of claim 1, wherein each of the second gate-all-around transistors includes the bottom dielectric isolation layer in contact with the second drain/source regions.

3. The device of claim 1, wherein each of the second gate-all-around transistors includes a first segment of the bottom dielectric isolation layer under one of the second drain/source regions and a second segment of the bottom dielectric isolation layer under another one of the second drain/source regions.

4. The device of claim 3, wherein the first segment is in contact with the one of the second drain/source regions and the second segment is in contact with the other one of the second drain/source regions.

5. The device of claim 1, wherein each of the second gate-all-around transistors includes a segment of the bottom dielectric isolation layer that extends from one of the second drain/source regions to another one of the second drain/source regions.

6. The device of claim 5, wherein the segment is in contact with the one of the second drain/source regions and the other one of the second drain/source regions.

7. The device of claim 1, wherein at least one of the second gate-all-around transistors includes a first segment of the bottom dielectric isolation layer under a first one of the second drain/source regions and a second segment of the bottom dielectric isolation layer under a second one of the second drain/source regions, and at least another one of the second gate-all-around transistors includes a third segment of the bottom dielectric isolation layer that extends from a third one of the second drain/source regions to a fourth one of the second drain/source regions.

8. The device of claim 1, wherein the sense amplifier includes third gate-all-around transistors that each include third drain/source regions and a bottom dielectric isolation layer under the third drain/source regions.

9. The device of claim 1, wherein the sense amplifier and the bit cells are situated on one plane of the semiconductor device.

10. A semiconductor device, comprising:
a substrate;
at least one sense amplifier that includes first gate-all-around transistors that have first drain/source regions that extend into the substrate; and
bit cells that include indium gallium zinc oxide (IGZO) transistors, each of the bit cells is connected to the at least one sense amplifier and configured to store at least one bit of data in a fuse or an anti-fuse.

11. The device of claim 10, wherein each of the IGZO transistors is connected to a fuse memory element.

12. The device of claim 10, wherein each of the bit cells includes at least two IGZO transistors connected in series to provide an anti-fuse bit cell.

13. The device of claim 10, wherein the at least one sense amplifier is situated on a first plane of the semiconductor device and the bit cells are situated on at least one second plane of the semiconductor device that is different than the first plane of the semiconductor device.

14. The device of claim 13, wherein the at least one second plane is situated directly above the first plane.

15. The device of claim 10, wherein the at least one sense amplifier includes second gate-all-around transistors that each include second drain/source regions and a bottom dielectric isolation layer under the second drain/source regions.

16. A method of manufacturing a semiconductor device, the method comprising:
forming a substrate;
forming first gate-all-around transistors including forming first drain/source regions that extend into the substrate, the first gate-all-around transistors are part of at least one sense amplifier;
forming second gate-all-around transistors including forming a bottom dielectric isolation layer and forming second drain/source regions above the bottom dielectric isolation layer; and
forming fuse memory elements such that at least one of the second gate-all-around transistors is connected to at least one of the fuse memory elements.

17. The method of claim 16, wherein forming the second gate-all-around transistors includes forming the second drain/source regions in contact with the bottom dielectric isolation layer.

18. The method of claim 16, wherein forming the second gate-all-around transistors includes forming one of the second drain/source regions above a first segment of the bottom dielectric isolation layer and forming another one of the second drain/source regions above a second segment of the bottom dielectric isolation layer.

19. The method of claim 16, wherein forming the second gate-all-around transistors includes forming one of the second drain/source regions and another one of the second drain/source regions above a segment of the bottom dielectric isolation layer that extends from the one of the second drain/source regions to the other one of the second drain/source regions.

20. The method of claim 16, wherein forming the second gate-all-around transistors includes forming a first one of the second drain/source regions above a first segment of the bottom dielectric isolation layer and forming a second one of the second drain/source regions above a second segment of the bottom dielectric isolation layer, and forming a third one of the second drain/source regions and a fourth one of the second drain/source regions above a third segment of the bottom dielectric isolation layer that extends from the third one of the second drain/source regions to the fourth one of the second drain/source regions.
